(19) United States
(12) Patent Application Publication
(10) Pub. No.: US 2012/0227940 A1
(43) Pub. Date: Sep. 13, 2012

(54) Toroidal Fluid Mover and Associated Heat Sink

(75) Inventor: Daniel Thomas, Las Vegas, NV (US)

(73) Assignee: NOVEL CONCEPTS, INC., Las Vegas, NV (US)

(21) Appl. No.: 13/043,292

(22) Filed: Mar. 8, 2011

(51) Int. Cl. H05K 7/20

(52) U.S. Cl. 165/120

(57) ABSTRACT

An apparatus includes a toroidal fluid mover. A drive mechanism rotates the toroidal fluid mover, such that the toroidal fluid mover directs axially received fluid at a smaller radius in a radial direction towards a greater radius to produce an axial-to-radial fluid flow field. A heat sink is positioned within the axial-to-radial fluid flow field. The heat sink is thermally coupled with a heat generating source and is at least partially filled with a fluid.

### FIELD OF THE INVENTION

The present invention relates generally to heat transfer and cooling of electronic components, such as semiconductor chips used in computers and telecommunication equipment. More particularly, the invention relates to a toroidal fluid mover and associated heat sink.

### BACKGROUND OF THE INVENTION

As the power of semiconductor chips increases, more efficient cooling devices are required. Current cooling solutions have drawbacks in providing adequate cooling to chips in small spaces. Drawbacks include fan size and heat transfer inefficiencies stemming from low velocity fluid adjacent to heat sink surfaces. Current cooling solutions also have acoustic noise disadvantages from the periodic fluid flow and pressure pulsations inherent to fans with propellers or blades. This acoustic noise is a small scale version of the acoustic thumping of helicopter blades. This propeller, or blade induced, periodic fluid flow and pressure pulsations result in heat transfer inefficiencies.

Therefore, it would be desirable to provide a cooling apparatus that obviates the aforementioned deficiencies in the prior art.

### SUMMARY OF THE INVENTION

In one embodiment of the invention, an apparatus includes a toroidal fluid mover. A drive mechanism rotates the toroidal fluid mover, such that the toroidal fluid mover directs axially received fluid at a smaller radius in a radial direction towards a greater radius to produce an axial-to-radial fluid flow field. A heat sink is positioned within the axial-to-radial fluid flow field. The heat sink is thermally coupled with a heat generating source and is at least partially filled with a fluid.

In another embodiment of the invention, an apparatus includes a toroidal fluid mover with an outer perimeter. A drive mechanism rotates the toroidal fluid mover, such that the toroidal fluid mover directs axially received fluid at a smaller radius in a radial direction towards a greater radius to produce an axial-to-radial fluid flow field. A heat sink substantially surrounds the outer perimeter of the toroidal fluid mover and is thereby positioned within a radial region of the axial-to-radial fluid flow field. The heat sink is thermally coupled with a heat generating source positioned within the radial region of the axial-to-radial fluid flow field.

### BRIEF DESCRIPTION OF THE FIGURES

The invention is more fully appreciated in connection with the following detailed description taken in conjunction with the accompanying drawings, in which:

FIG. 1 depicts a three-dimensional (3-D) dimetric section view of a toroidal fluid mover, having a rectangular profile, and a hollow heat sink element;

FIG. 2 depicts a three-dimensional (3-D) dimetric view of a toroidal fluid mover, having a rectangular profile, and a heat sink element with attached heat sources;

FIG. 3 depicts a three-dimensional (3-D) dimetric view of a toroidal fluid mover, having a rectangular profile, and a heat sink element with a heat source attached to a parallel appendage;

FIG. 4 depicts a three-dimensional (3-D) dimetric view of a toroidal fluid mover, having a rectangular profile, and a heat sink element with a perpendicular appendage and an offset region, each with a heat source;

FIG. 5 depicts a three-dimensional (3-D) dimetric view of a toroidal fluid mover, having a rectangular profile, a heat sink element with multiple perpendicular appendages and corresponding heat sources;

FIG. 6 depicts a three-dimensional (3-D) dimetric view of a toroidal fluid mover, having a rectangular profile, a heat sink element with recessed and protruding regions and corresponding heat sources;

FIG. 7 depicts a three-dimensional (3-D) dimetric view of a toroidal fluid mover, having a rectangular profile, a heat sink element with separate fluid pump and fluid coupled heat sources;

FIG. 8 depicts a three-dimensional (3-D) dimetric view of a toroidal fluid mover, having a rectangular profile, a heat sink element with heat sources attached to a parallel appendage, and an embedded fluid pump;

FIG. 9 depicts a three-dimensional (3-D) dimetric view of two toroidal fluid movers, each having a rectangular profile, and two heat sink elements joined by a perpendicular appendage with attached heat sources;

FIG. 10 depicts a three-dimensional (3-D) dimetric view of two toroidal fluid movers, each having a rectangular profile, and having different rotational axes, an L-shaped heat sink element with heat sources, and an embedded fluid pump;

FIG. 11 depicts a three-dimensional (3-D) dimetric view of a toroidal fluid mover, having a rectangular profile, a non-circular heat sink element with heat sources, an embedded fluid pump, and a radial section of extended surfaces;

FIG. 12 depicts a three-dimensional (3-D) dimetric view of a toroidal fluid mover, having a rectangular profile, a non-circular heat sink element with heat sources, an embedded fluid pump, and a radial array of extended surfaces;

FIG. 13 depicts a three-dimensional (3-D) dimetric view of a toroidal fluid mover, having a rectangular profile, a non-circular heat sink element with heat sources, an embedded fluid pump, and an array of extended surfaces;

FIG. 14 depicts a three-dimensional (3-D) dimetric view of a toroidal fluid mover, having a rectangular profile, a non-circular heat sink element with heat sources, an embedded fluid pump, an array of extended surfaces, and a fluid flow diverting element;

FIG. 15 depicts a three-dimensional (3-D) dimetric view of a toroidal fluid mover, having a rectangular profile, a non-circular heat sink element with heat sources, an embedded fluid pump, an array of extended surfaces, and a fluid flow diverting element, on two sides of the heat sink element;

FIG. 16 depicts a three-dimensional (3-D) dimetric view of a toroidal fluid mover, having a rectangular profile, a portion of non-circular heat sink element with heat sources, and an embedded fluid pump;

FIG. 17 depicts a three-dimensional (3-D) dimetric section view of a toroidal fluid mover, having a rectangular profile and extended surface features, and a heat sink element with extended surface features;

FIG. 18 depicts a three-dimensional (3-D) dimetric section view of a toroidal fluid mover, having a rectangular profile and apertures, and a heat sink element;

FIG. 19 depicts a three-dimensional (3-D) dimetric section view of a toroidal fluid mover, having a rectangular profile and recessed surface features, and a heat sink element;

FIG. 20 depicts a three-dimensional (3-D) dimetric section view of a toroidal fluid mover, having a rectangular profile and a combination surface features, and a heat sink element;

FIG. 21 depicts a three-dimensional (3-D) dimetric section view of a toroidal fluid mover, having a rectangular profile, axially offset from a heat sink element;

FIG. 22 depicts a three-dimensional (3-D) dimetric section view of a toroidal fluid mover, having a rectangular profile, axially offset from two heat sink elements;

FIG. 23 depicts a three-dimensional (3-D) dimetric section view of a toroidal fluid mover, having a rectangular profile, axially offset from two heat sink elements having extended surface features;

FIG. 24 depicts a three-dimensional (3-D) dimetric section view of two toroidal fluid movers, having rectangular profiles, axially offset from a heat sink element;

FIG. 25 depicts a three-dimensional (3-D) dimetric section view of two toroidal fluid movers, having rectangular profiles, axially offset from a heat sink element having extended surface features;

FIG. 26 depicts a three-dimensional (3-D) dimetric section view of a toroidal fluid mover, having a trapezoidal profile, and a heat sink element;

FIG. 27 depicts a three-dimensional (3-D) dimetric section view of a toroidal fluid mover, having a trapezoidal profile, and a heat sink element having a trapezoidal profile;

FIG. 28 depicts a three-dimensional (3-D) dimetric section view of a toroidal fluid mover, having a leading edge feature, and a heat sink element;

FIG. 29 depicts a three-dimensional (3-D) dimetric section view of a toroidal fluid mover, having a trailing edge feature, and a heat sink element;

FIG. 30 depicts a three-dimensional (3-D) dimetric section view of a toroidal fluid mover, having a leading edge feature and non-planar surfaces, and a heat sink element;

FIG. 31 depicts a three-dimensional (3-D) dimetric section view of a toroidal fluid mover, having a curved profile, and a heat sink element;

FIG. 32 depicts a three-dimensional (3-D) dimetric section view of a toroidal fluid mover, having a curved profile with swept apertures, and a heat sink element;

FIG. 33 depicts a three-dimensional (3-D) dimetric section view of a toroidal fluid mover, having a curved profile with swept surface features, and a heat sink element;

FIG. 34 depicts a three-dimensional (3-D) dimetric section view of a toroidal fluid mover, having a curved profile with swept surface features, and a curved heat sink element;

FIG. 35 depicts a three-dimensional (3-D) dimetric section view of a toroidal fluid mover, having a curved profile, axially offset and overlapping a curved heat sink element;

FIG. 36 depicts a three-dimensional (3-D) dimetric section view of a toroidal fluid mover, having a rectangular profile, axially offset and overlapping a heat sink element;

FIG. 37 depicts a three-dimensional (3-D) dimetric section view of a toroidal fluid mover, having a substantially trapezoidal profile, with circumferential features, and a heat sink element having a substantially trapezoidal profile, with circumferential features;

FIG. 38 depicts a three-dimensional (3-D) dimetric view of a rotating toroidal fluid mover, having a revolved spiral cut, and a heat sink element;

FIG. 39 depicts a three-dimensional (3-D) dimetric section view of a toroidal fluid mover, and a heat sink element, both having a rectangular profile, and a cut plot of velocity contours, from a computational fluid dynamics (CFD) analysis;

FIG. 40 depicts a three-dimensional (3-D) dimetric section view of a toroidal fluid mover, and a heat sink element, both having a curved profile, and a cut plot of velocity contours, from a computational fluid dynamics (CFD) analysis.

Like reference numerals refer to corresponding parts throughout the several views of the drawings.

### DETAILED DESCRIPTION OF THE INVENTION

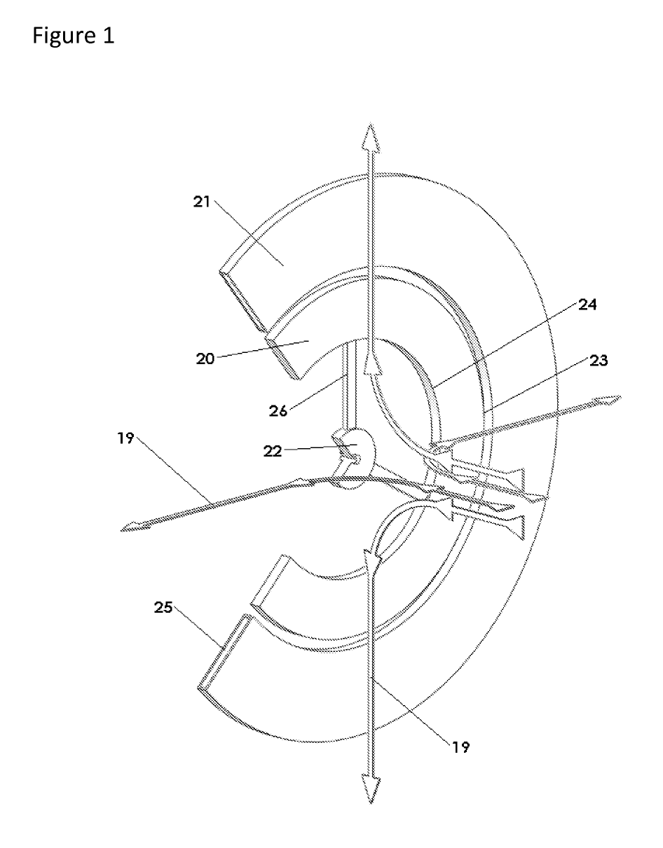

FIG. 1 depicts the cooling device of the present invention. As shown in the sectioned view of FIG. 1, the cooling device includes a rotating toroidal fluid mover 20 and a heat sink element 21. The toroidal fluid mover 20 is in the shape of a toroid. A toroid has an annular shape that is generated by revolving a geometrical figure around an axis external to that figure. When a rectangle is rotated around an axis parallel to one of its edges then a hollow cylinder is produced. If the revolved geometrical figure is a circle, then a torus is produced. As illustrated below, the invention may be implemented with various geometrical figures, such as trapezoids.

A motor 22 or other rotational means is attached to the toroidal fluid mover 20 by spokes 26. Motor rotation creates a centrifugal force resulting in a relatively high fluid flow and therefore relatively low pressure region near the outer periphery 23. Conversely, there is a relatively low fluid flow and therefore relatively high pressure region near the inner periphery 24. Fluid (e.g., air) from the environment moves axially toward the toroidal fluid mover. At each ingress point, the fluid is forced radially outward toward the low pressure region 23. This general flow path is shown with arrow 19. Although fluid flow pattern 19 is shown on one side, a mirror image of this fluid flow pattern is also on the opposite side of the radial plane.

This axial to radial fluid flow field enjoys mechanical efficiency due to the uninterrupted non-periodic nature of the fluid mover's smooth toroidal geometry. This mechanically efficient fluid flow field is directed toward the heat sink element 21, which is positioned within the flow field allowing heat from the heat sink element 21 to be efficiently transferred to this flow field. Furthermore, heat generating devices coupled to the heat sink's heat transfer surfaces experience high heat transfer efficiency to this flow field. Rotating toroidal fluid mover 20 may be fabricated from solid, hollow, or porous materials. Heat sink element 21 may also be fabricated from solid, hollow, or porous materials. The heat sink element may have at least one interior void 25 at least partially filled with fluid. This fluid may be free convecting, forced convecting, capillary driven, or moved by any other fluid moving means.

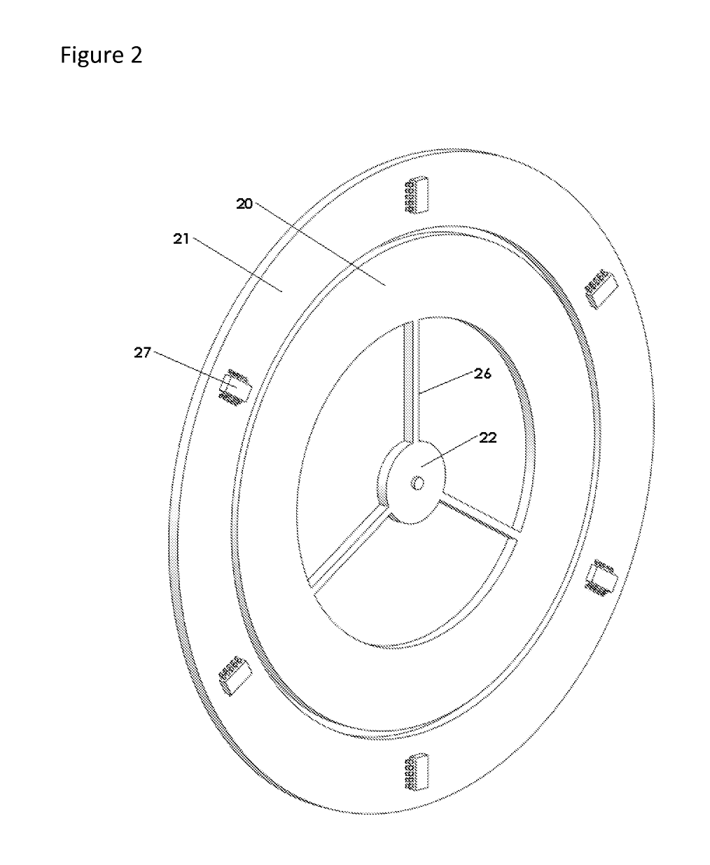

FIG. 2 depicts a rotating toroidal fluid mover 20, and a heat sink element 21 having attached heat sources 27. Additionally, heat sink element 21 may be an electrical circuit board, have an electrical circuit means incorporated thereon, or separately attached. Heat sources may be attached directly or indirectly, through a circuit board attachment, or any other heat source packaging or attachment means.

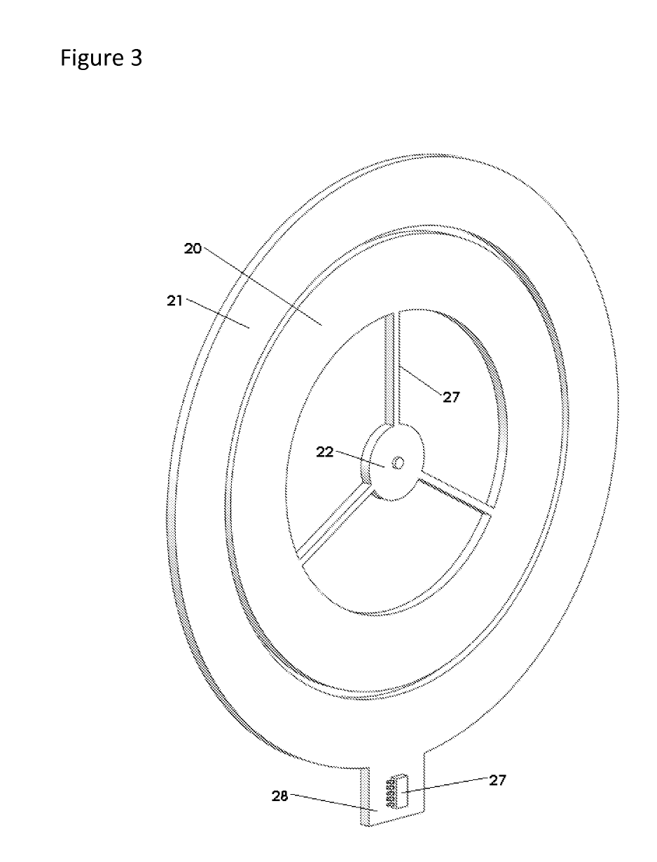

FIG. 3 depicts a rotating toroidal fluid mover 20, and a heat sink element 21 having heat source 27 attached to coplanar appendage 28. This appendage provides additional area for the attachment of heat sources.

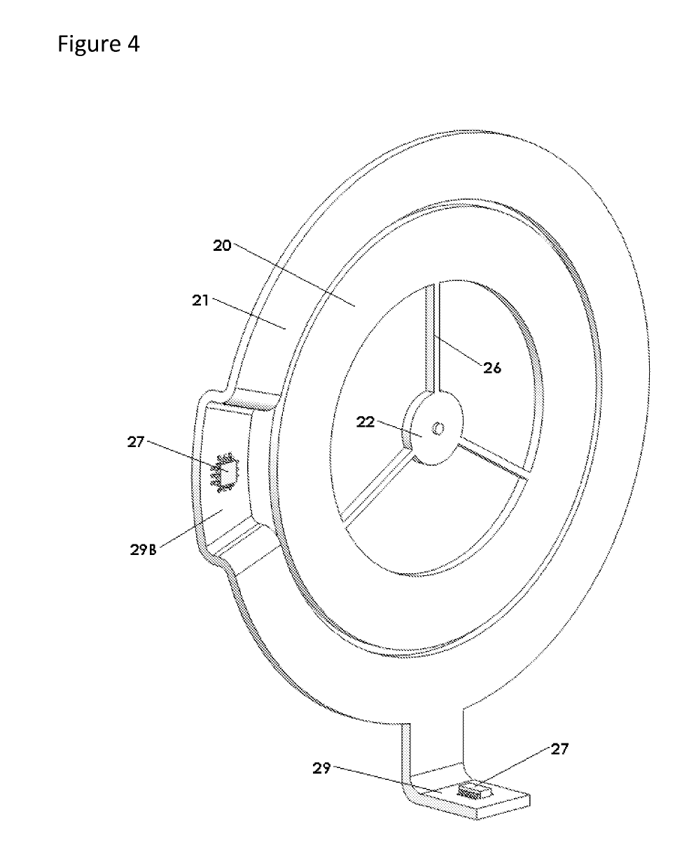

FIG. 4 depicts a rotating toroidal fluid mover 20, and a heat sink element 21 having heat source 27 attached to non-coplanar appendage 29. This appendage also provides additional area for the attachment of heat sources. Further, this non-coplanar appendage may be optimized to improve fluid flow field impingement. This figure also depicts an offset region 29B with an associated heat source 27. This offset region allows thermal communication with heat sources that are not coplanar with heat sink 21. Although appendage 29 is shown as being perpendicular to heat sink 21, and an offset region 29B is shown as parallel to heat sink 21, these features may have any spatial orientation. This spatial orientation may be optimized for fluid dynamic drag and fluid flow field impingement for improved heat transfer efficiency.

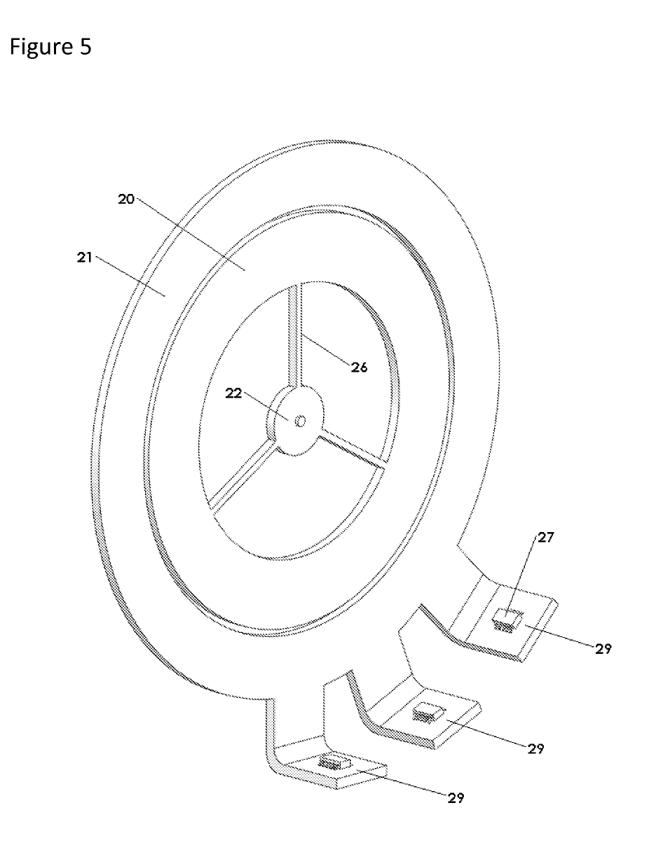

FIG. 5 depicts a rotating toroidal fluid mover 20 and a heat sink element 21 having heat source 27 attached to multiple non-coplanar appendages 29. These multiple appendages provide additional area for the attachment of heat sources. These appendages may also have independent spatial orientation. These orientations may be optimized for non-thermal goals, such as converging or diverging LED light source angles.

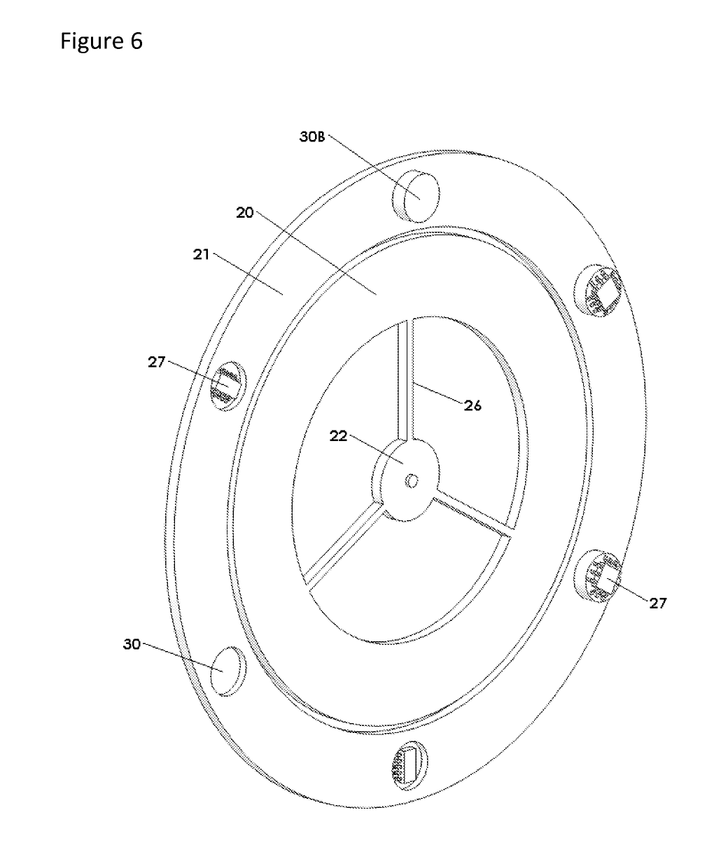

FIG. 6 depicts a rotating toroidal fluid mover 20 and a heat sink element 21 having attached heat sources 27, at least partially within recessed regions 30. The recessed heat sources may be optimized for lower fluid dynamic drag and fluid flow field impingement. FIG. 6 also depicts heat sink element 21 having protruded regions 30B and corresponding heat sources 27. Although recessed regions 30 and protruded regions 30B are shown as parallel to heat sink 21, these features may have any spatial orientation, and this spatial orientation may be optimized for fluid dynamic drag and fluid flow field impingement, resulting in improved heat transfer efficiency.

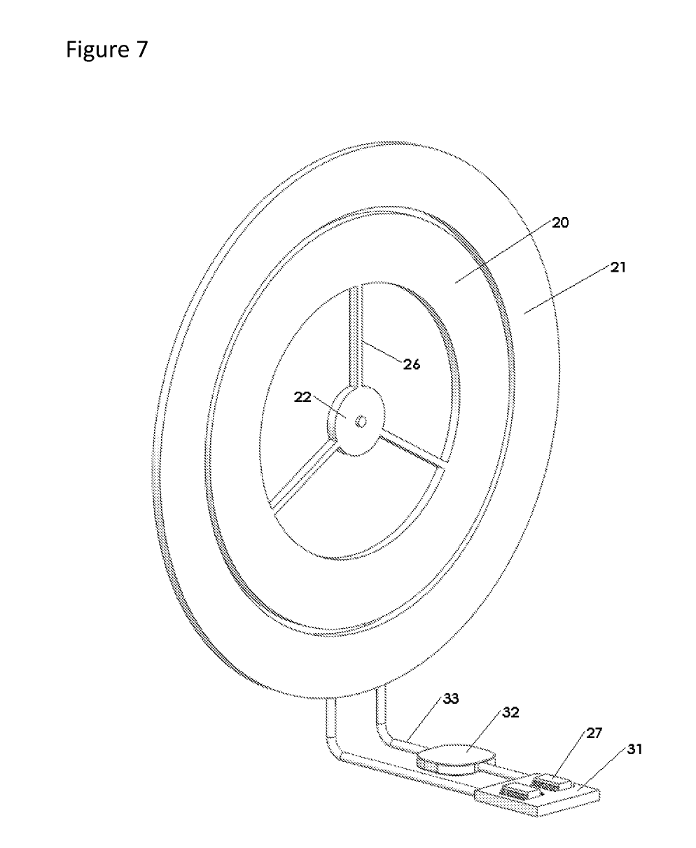

FIG. 7 depicts a rotating toroidal fluid mover 20 and a heat sink element 21 having a separate heat distribution means 31, a separate fluid pump 32, and fluid interconnect 33. Heat from attached heat source 27 migrates to heat distribution means 31 and is further distributed to heat sink element 21 through an internal fluid circuit within heat sink element 21. Fluid circulation is provided by fluid pump 32 and fluid interconnect 33.

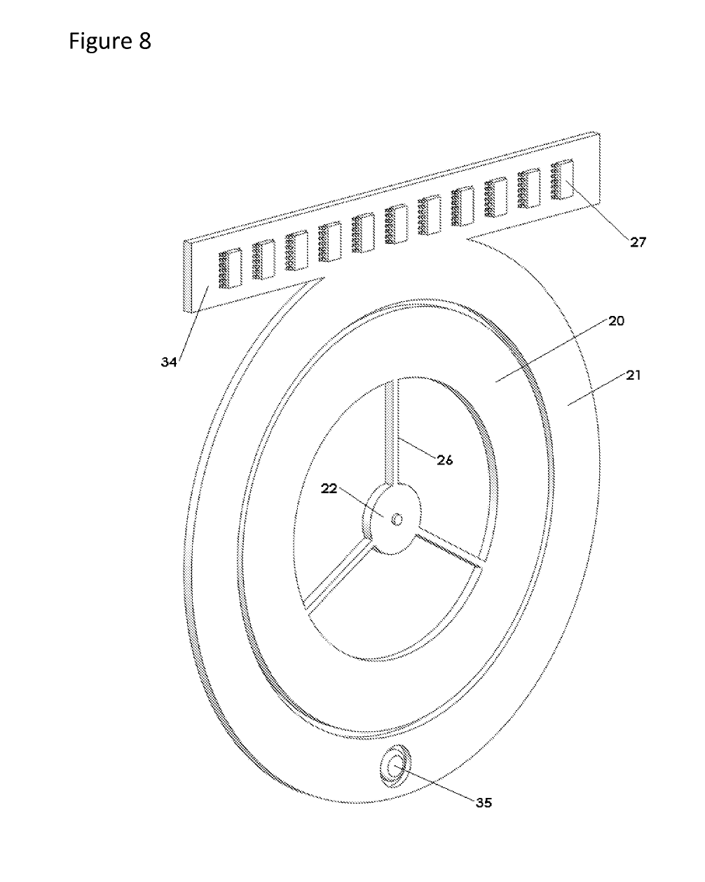

FIG. 8 depicts a rotating toroidal fluid mover 20 and a heat sink element 21 having multiple heat sources 27 attached to a bifurcated coplanar appendage 34. This bifurcated appendage provides additional area for the attachment of heat sources. Heat from attached heat sources 27 is distributed to heat sink element 21 through an internal fluid circuit within heat sink element 21. Fluid circulation is provided by fluid pump 35. Additionally, appendage 34 may have an internal fluid circuit, which may be interconnected with the fluid circuit within heat sink element 21. Fluid pump 35 may be at least partially embedded into heat sink element 21, or may be at least partially embedded into appendage 34.

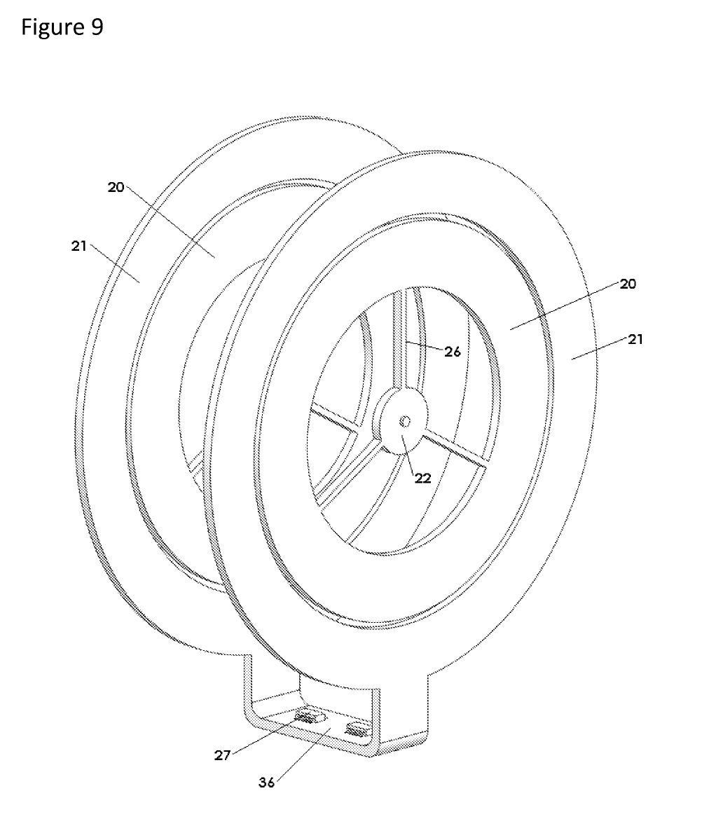

FIG. 9 depicts two rotating toroidal fluid movers 20 and two heat sink elements 21 interconnected by heat sink element interconnect appendage 36. Heat sources 27 are attached to heat sink element interconnect appendage 36. Having multiple rotating toroidal fluid movers 20 and two heat sink elements 21 allows for improved cooling. Although the two rotating toroidal fluid movers 20 are shown as being parallel and on the same rotational axis, they may be oblique and have independent axes. Further, the rotating toroidal fluid movers 20 and heat sink elements 21 may have independent design elements, such as materials, construction, size, shape, angular velocity, and angular direction. Still further, the number of fluid movers and heat sink elements may not be equal, and may be greater than two.

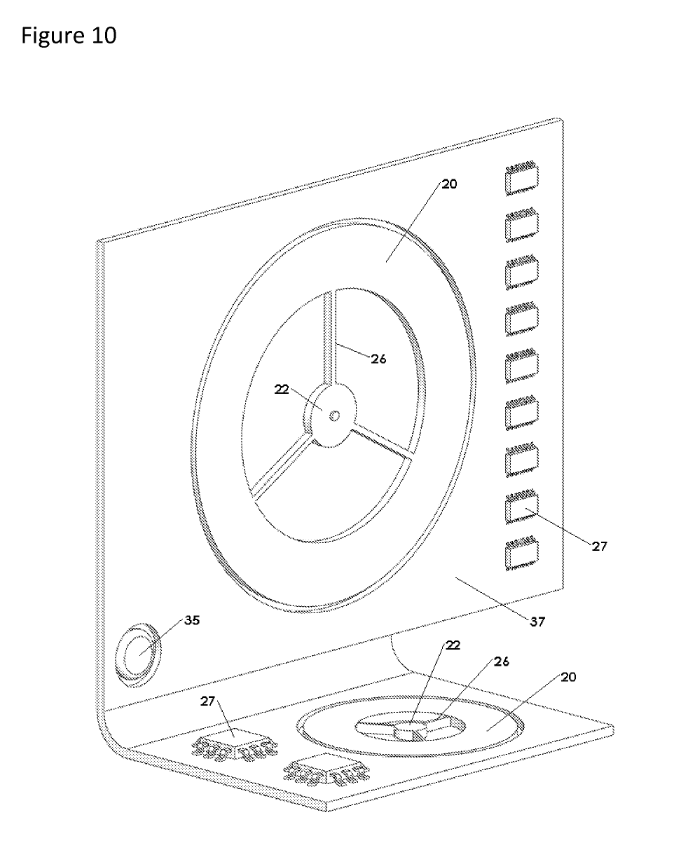

FIG. 10 depicts two rotating toroidal fluid movers 20 and an L-shaped heat sink element 37 having multiple heat sources 27 attached. Heat from attached heat sources 27 is distributed to L-shaped heat sink element 37 through an internal fluid circuit within heat sink element 37 by fluid circulation means provided by fluid pump 35. Heat is removed from heat sink element 37 and from heat sources 27 by fluid moving along their surfaces. Fluid pump 35 may be at least partially embedded into heat sink element 37. Heat sink element 37 may have an electrical circuit means incorporated thereon, or may be separately attached. This electrical circuit means may provide at least communication and power to heat sources and other electrical components, including fluid pump 35. Heat sources may be attached directly or indirectly, through a circuit board attachment, or any other heat source packaging or attachment means. The two rotating toroidal fluid movers 20 have different sizes and independent rotational axes. Further, the rotating toroidal fluid movers 20, and heat sink elements 21 may have independent design elements, such as materials, construction, size, shape, angular velocity, and angular direction. Still further, the number of fluid movers and heat sink elements are not equal.

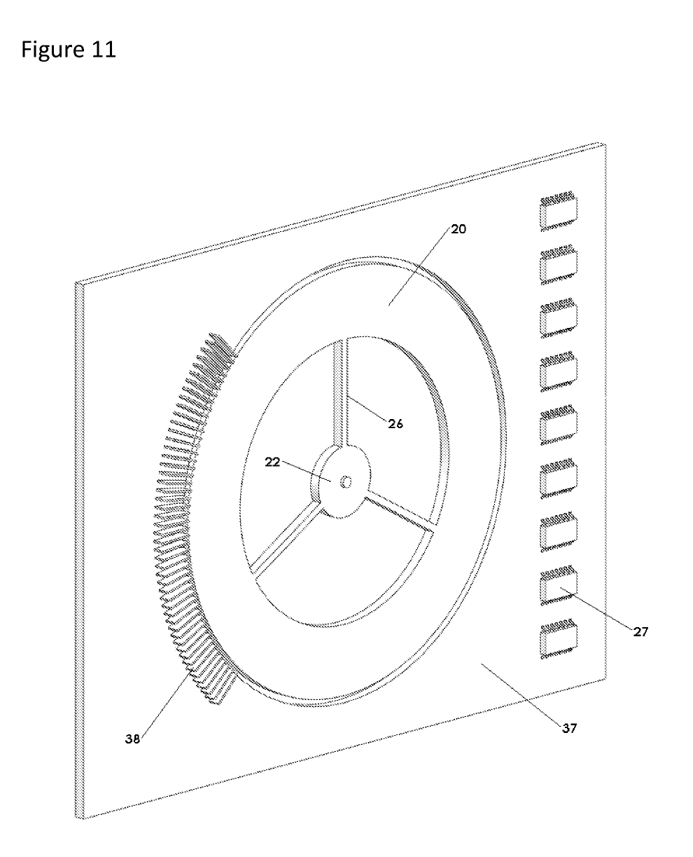

FIG. 11 depicts a rotating toroidal fluid mover 20 and a non-circular heat sink element 37 having multiple heat sources 27 attached. Additionally, a radial section of extended surfaces 38 is attached to non-circular heat sink element 37. Heat from attached heat sources 27 is distributed to extended surfaces 38 through heat sink element 37. Heat is transferred from heat sink element 37 and extended surfaces 38 to moving fluid provided by toroidal fluid mover 20. Extended surfaces 38 improve heat transfer efficiency by increasing surface area within the fluid flow field generated by toroidal fluid mover 20. Heat sink element 37 may be solid, partially filled with a phase changing fluid, or any other heat transfer body. Heat sink element 37 may have an electrical circuit incorporated thereon, or may be separately attached. The electrical circuit may provide at least communication and power to heat sources and other electrical components.

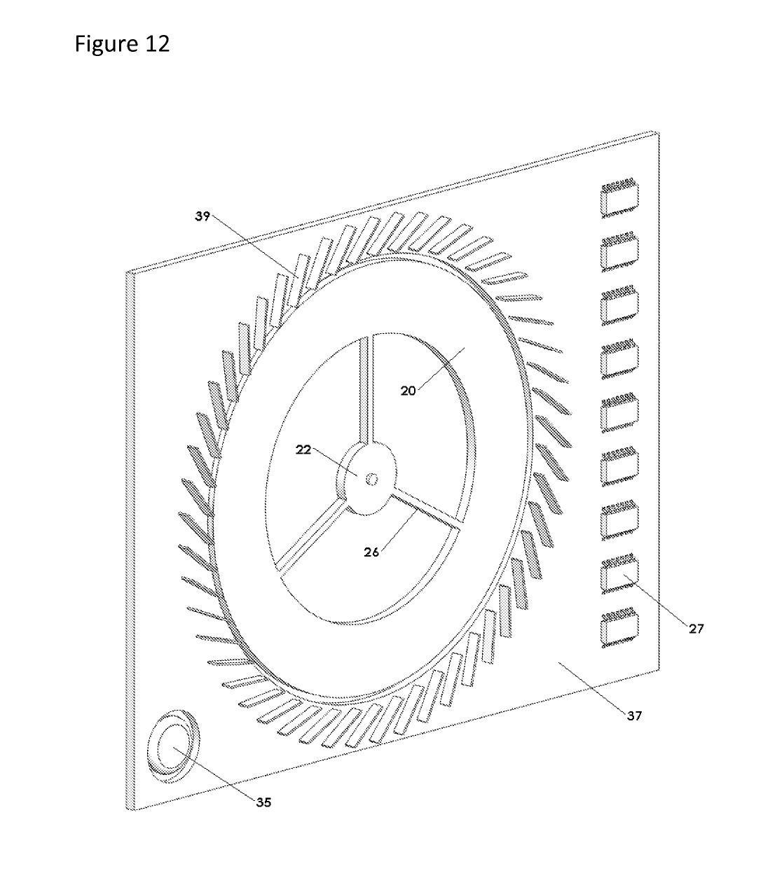

FIG. 12 depicts a rotating toroidal fluid mover 20 and a non-circular heat sink element 37 having multiple heat sources 27 attached. Additionally, a radial array of extended surfaces 39 is attached to non-circular heat sink element 37. Heat from attached heat sources 27 is distributed to extended surfaces 39 through an internal fluid circuit within heat sink element 37 by fluid circulation means provided by fluid pump 35.

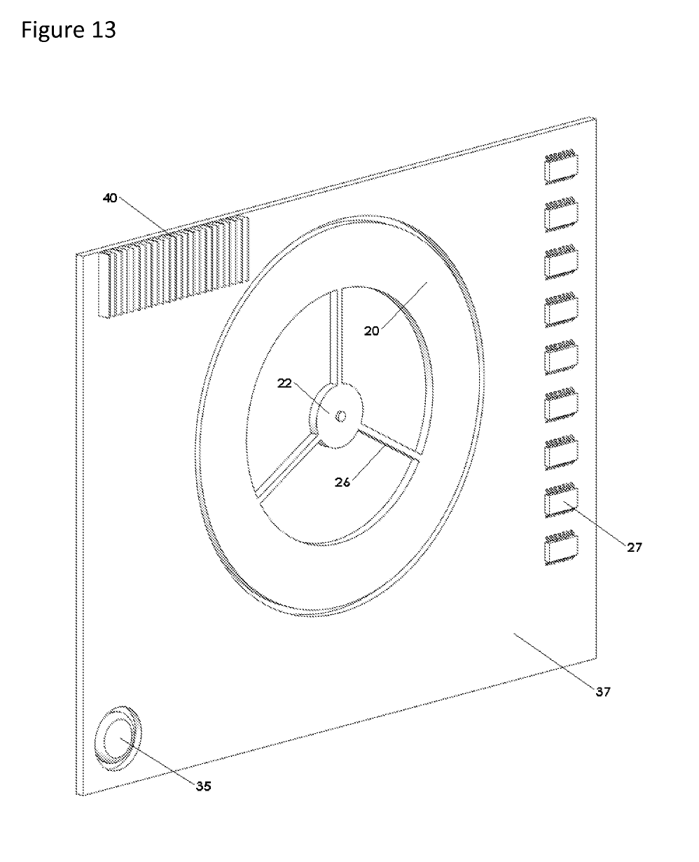

FIG. 13 depicts a rotating toroidal fluid mover 20 and a non-circular heat sink element 37 having multiple heat sources 27 attached. Additionally, an array of extended surfaces 40 is attached to non-circular heat sink element 37. Heat from attached heat sources 27 is distributed to extended surfaces 40 through an internal fluid circuit within heat sink element 37. Heat distribution may be enhanced by fluid circulation means provided by fluid pump 35.

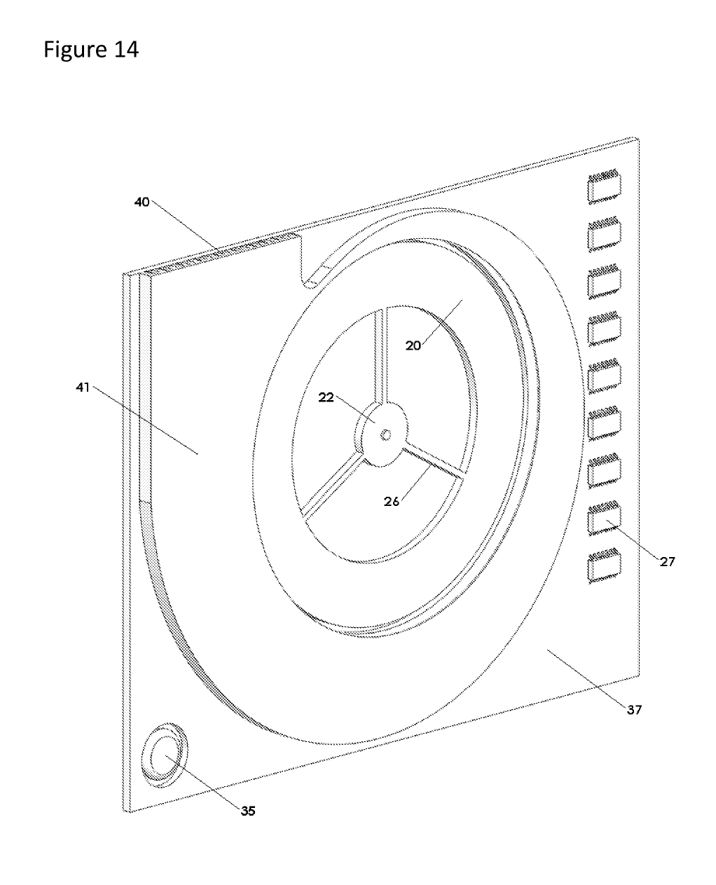

FIG. 14 depicts a rotating toroidal fluid mover 20, and a non-circular heat sink element 37 having multiple heat sources 27 attached. Similar to FIG. 13, an array of extended surfaces 40 is attached to non-circular heat sink element 37. Additionally, a fluid flow diverting element 41 redirects the fluid flow from the rotating toroidal fluid mover 20, toward the array of extended surfaces 40. Heat from attached heat sources 27 is distributed to extended surfaces 40 through an internal fluid circuit within heat sink element 37. Fluid circulation may be enhanced with fluid pump 35. Heat is transferred from heat sink element 37 and extended surfaces 40 to moving fluid provided by toroidal fluid mover 20. Further, redirected fluid flow from fluid flow diverting element 41 provides additional benefits, such as cooling additional components within its flow field or redirecting fluid flow to an enclosure fluid exit.

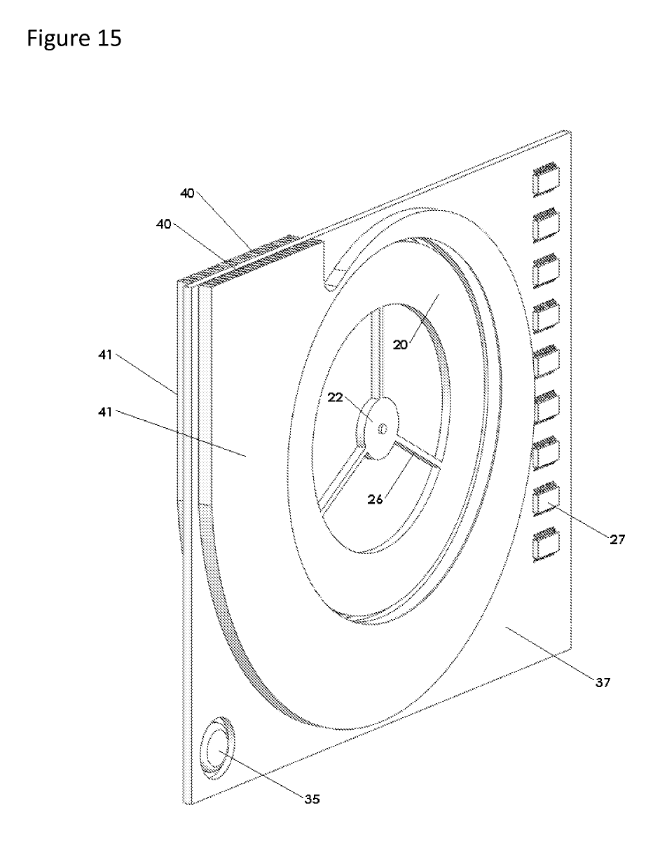

FIG. 15 depicts a rotating toroidal fluid mover 20 and a non-circular heat sink element 37 having multiple heat sources 27 attached. Similar to FIG. 14, two arrays of extended surfaces 40 and fluid flow diverting elements 41 are attached to opposite sides of non-circular heat sink element 37. Having multiple arrays of extended surfaces, as well as multiple fluid flow diverting elements redirecting fluid flow toward those extended surfaces improves heat transfer efficiency.

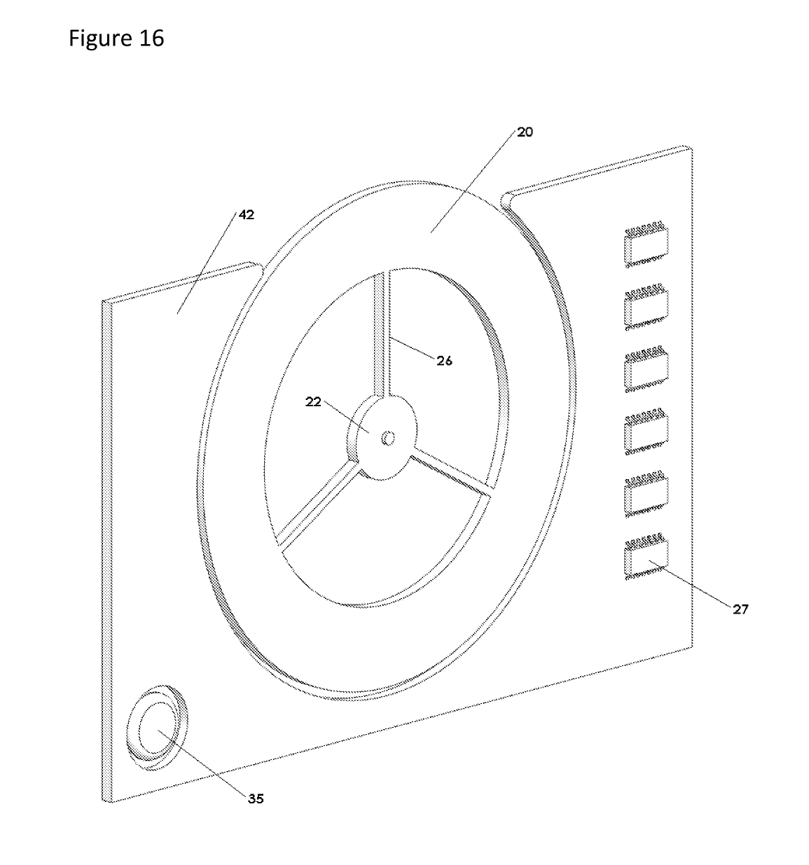

FIG. 16 depicts a rotating toroidal fluid mover 20 and a non-circumferentially encompassing heat sink element 42 having multiple heat sources 27 attached. This non-circumferentially encompassing heat sink element 42 allows additional degrees of design freedom, such as a toroidal fluid mover that is larger than the heat sink element or a single toroidal fluid mover used between two or more heat sink elements.

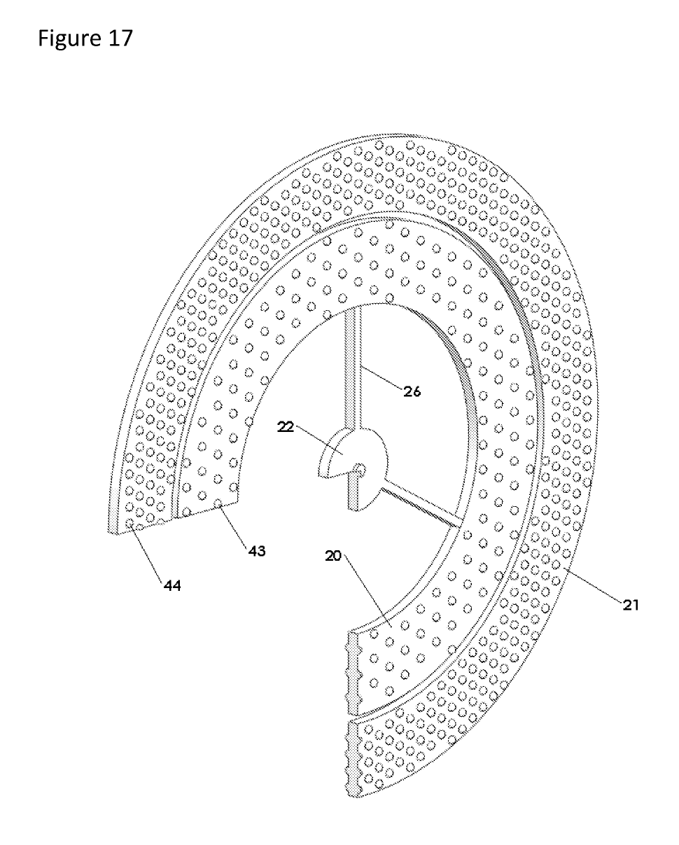

FIG. 17 depicts a rotating toroidal fluid mover 20 having extended surface features 43 and a heat sink element 21 having extended surface features 44. These extended surface features may, or may not have the same design goal, and may be independently optimized. For instance, extended surface features 43 on fluid mover 20, may be optimized to promote fluid flow by increasing surface area, while extended surface features 44 may be optimized to improve heat transfer efficiency by also increasing surface area. Although these extended surface features are shown as hemispherical they may have any shape, size, quantity, or pattern. Additionally, they may be on one or more surfaces and may have varying positional density. Further, these extended surface features may have multiple shapes and sizes on any given surface.

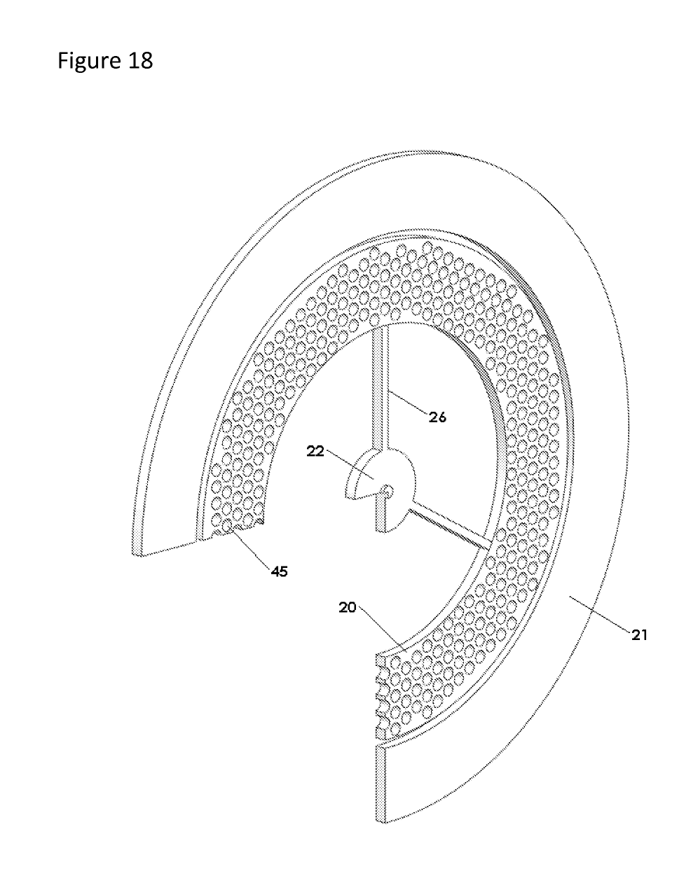

FIG. 18 depicts a rotating toroidal fluid mover 20 having apertures 45. These apertures may have multiple design goals, such as, improving fluid flow or reducing sound pressure. For instance, apertures closer to the rotational axis, or center, may be optimized for improving mass fluid flow rate, by having larger size and increasing surface area, while apertures near the outer periphery may be optimized for reducing sound pressure, by having smaller size and radially staggered. Although these apertures are shown as cylindrical, they may have any shape, size, quantity or pattern. Additionally, they may be on one or more surfaces and may have varying positional density. Further, these apertures may have multiple shapes and sizes on any given surface.

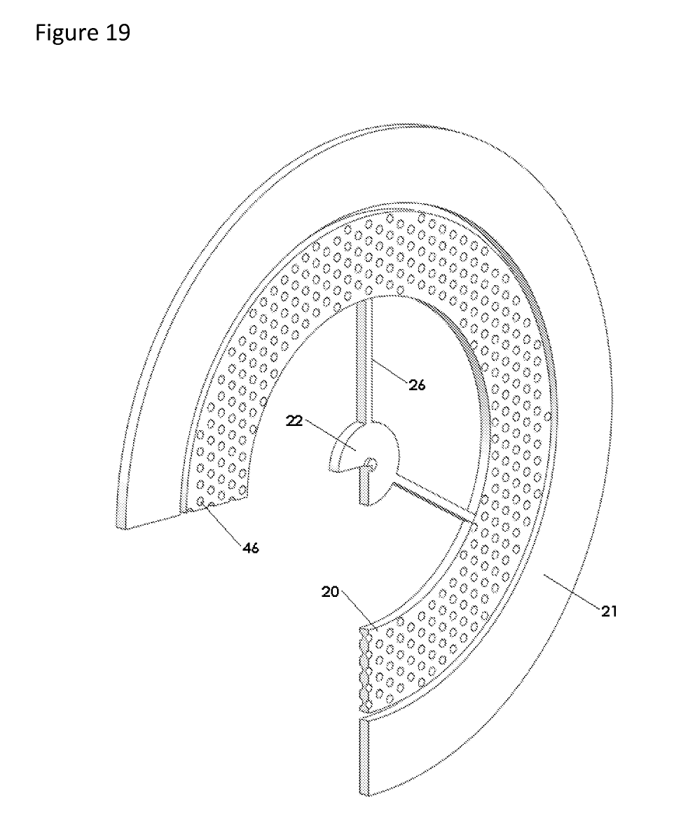

FIG. 19 depicts a rotating toroidal fluid mover 20 having recessed surface features 46. These recessed surface features, similar to those on a golf ball, may have multiple design goals, such as, improving fluid flow or reducing rotational torque, thus horsepower. For instance, recessed features closer to the rotational axis, or center, may be optimized for improving mass fluid flow rate, by having larger size and increasing surface area and edges, while recessed features near the outer periphery may be optimized for reducing rotational torque, by being smaller and radially staggered, like a golf ball. Although these recessed surface features are shown as hemispherical, they may have any shape, size, quantity, or pattern. Additionally, they may be on one or more surfaces, and may have varying positional density. Further, these recessed surface features may have multiple shapes and sizes on any given surface.

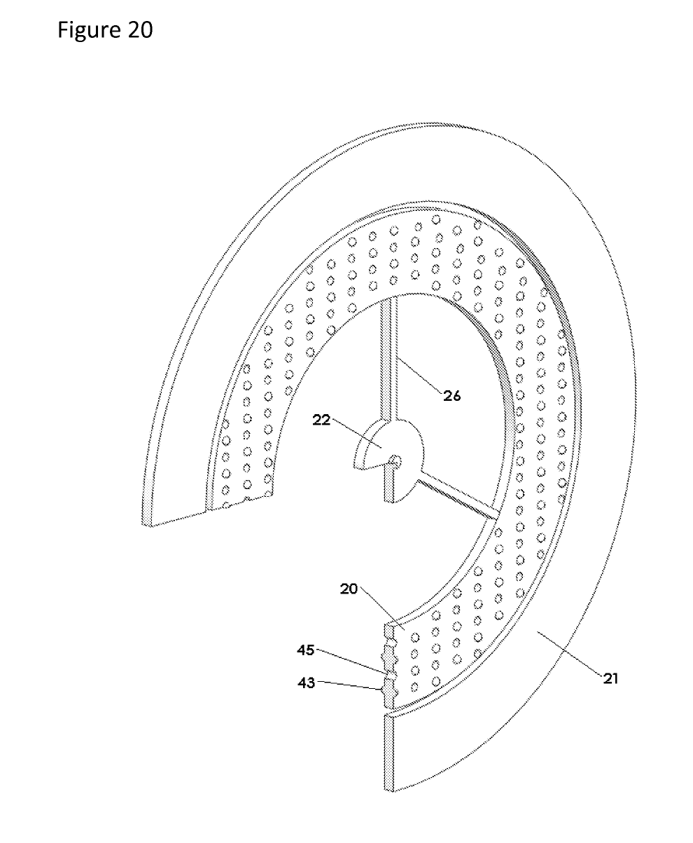

FIG. 20 depicts a rotating toroidal fluid mover 20 having both extended surface features 43 and apertures 45. This combination of extended surface features and apertures provides additional design degrees of freedom, such as increasing fluid flow while decreasing sound and rotational torque. For instance, extended surface features closer to the lower velocity centroid may be optimized for increasing mass fluid flow rate, while simultaneously optimizing apertures near the higher velocity outer periphery, toward a lower sound pressure goal. Although two types of features are shown, any combination of features may be used, including extended, recessed, or aperture type. Additionally, they may be on one or more surfaces, and may have varying positional density. Further, these surface features may be extended, recessed, or apertures, and may have multiple shapes and sizes on any given surface.

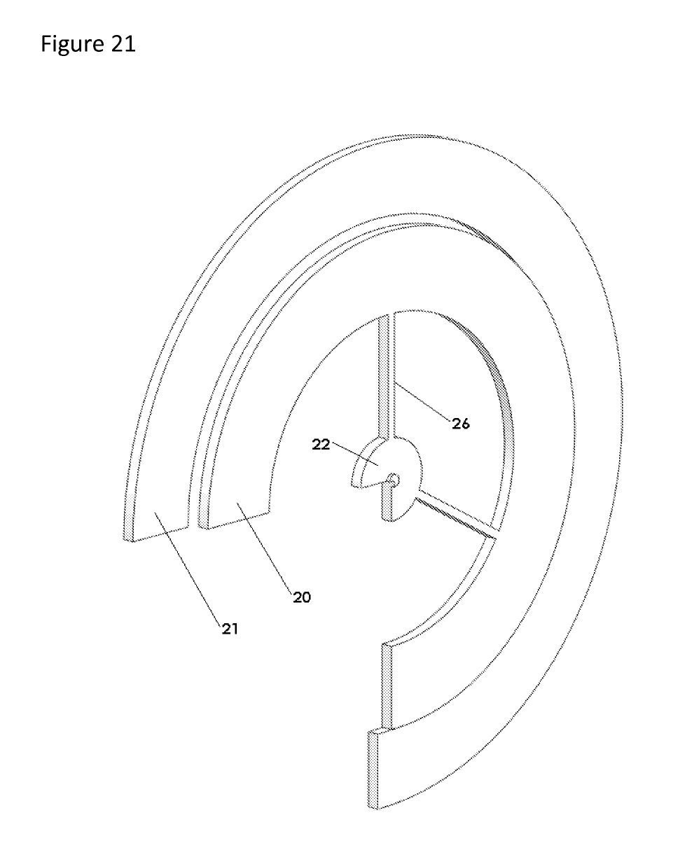

FIG. 21 depicts a rotating toroidal fluid mover 20 and a heat sink element 21, where the rotational plane of the toroidal fluid mover 20 is not coplanar with heat sink element 21. Offsetting the fluid mover plane from the heat sink element plane offsets the fluid flow field from the heat sink element plane. This offset allows more fluid flow on the offset side of the heat sink element. This offset feature provides cooling improvement when axial fluid intake is at least partially restricted from either axial side. Although the fluid mover plane is shown parallel to the heat sink element plane, these planes may not be coplanar or parallel.

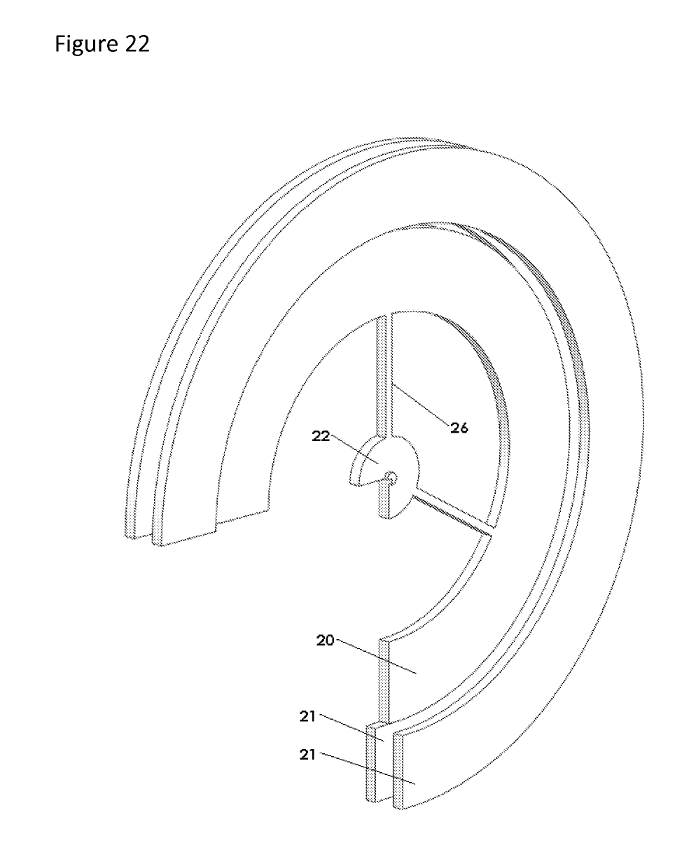

FIG. 22 depicts a rotating toroidal fluid mover 20 and two heat sink elements 21, where the rotational plane of the toroidal fluid mover 20 may not be coplanar with either heat sink element 21. Offsetting the fluid mover plane from the heat sink element plane offsets the fluid flow field from the heat sink element plane. This offset allows more fluid flow on the offset side of the heat sink element. This offset embodiment provides cooling improvement when fluid flow on one or both exterior heat sink surfaces may be at least partially restricted, such as proximate surfaces or attached heat generating devices.

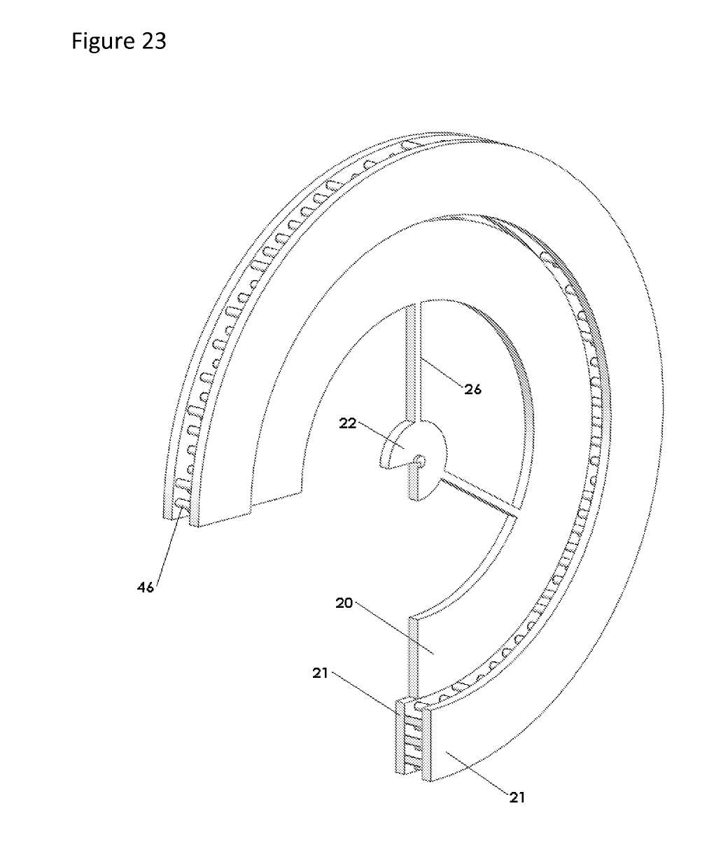

FIG. 23 depicts a rotating toroidal fluid mover 20 and two heat sink elements 21, having extended surface features 46 interposed. The rotational plane of toroidal fluid mover 20 may not be coplanar with either heat sink elements 21. These interposed extended surface features 46 are within the highest velocity region of the fluid flow field generated by this offset rotating toroidal fluid mover 20. Being within this high velocity region, these interposed extended surface features 46 have higher heat transfer efficiency. Although these interposed extended surface features 46 are show as cylindrical, they may have any shape, including multiple shapes, size, quantity, pattern, and may have varying positional density. In addition, interposed extended surface features may be optimized to provide a thermal path between the two heat sink elements, when the thermal load or cooling requirement of the heat sink elements is not equal.

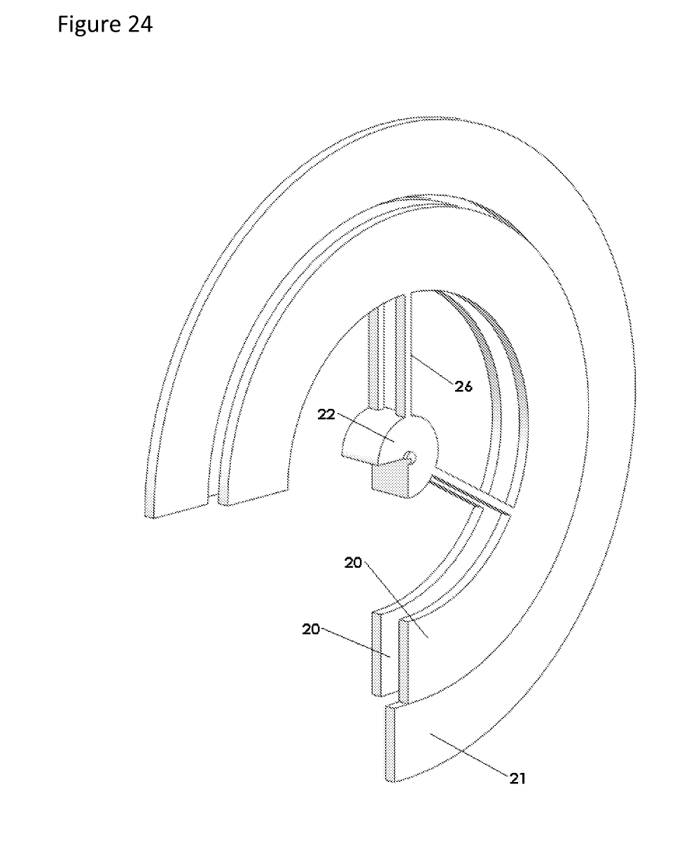

FIG. 24 depicts two rotating toroidal fluid movers 20, where the rotational planes of the toroidal fluid movers 20 may or may not coplanar with heat sink element 21. Offsetting the fluid mover planes from the heat sink element plane offsets the fluid flow fields from the heat sink element plane. These offset fluid flow fields allow more fluid flow on both sides of the heat sink element, for increased heat transfer efficiency. Although a single motor 22 may have multiple toroidal fluid movers, each rotating toroidal fluid mover 20 may have an independent motor. These independent motors may have different size, horsepower, angular velocity, and angular direction.

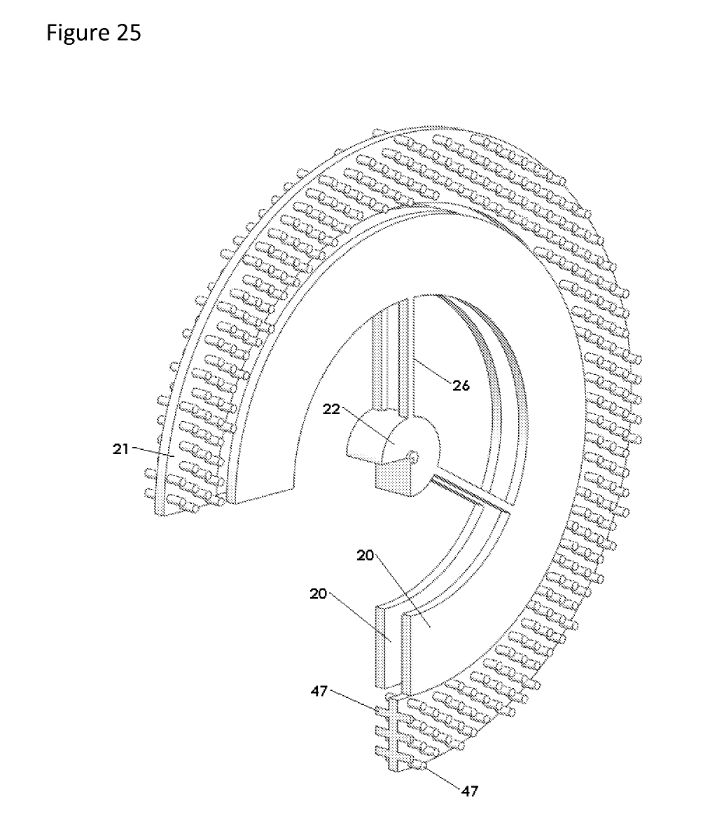

FIG. 25 depicts two rotating toroidal fluid movers 20 and a heat sink element 21 with extended surface features 47 on opposing sides. The rotational planes of toroidal fluid movers 20 may not be coplanar with heat sink element 21. The extended surface features 47 are within the highest velocity region of the fluid flow fields generated by these offset rotating toroidal fluid movers 20. Being within this high velocity region, these extended surface features 47 have higher heat transfer efficiency. Although these extended surface features 47 are show as cylindrical, they may have any shape, including multiple shapes, size, quantity, pattern, and may have varying positional density.

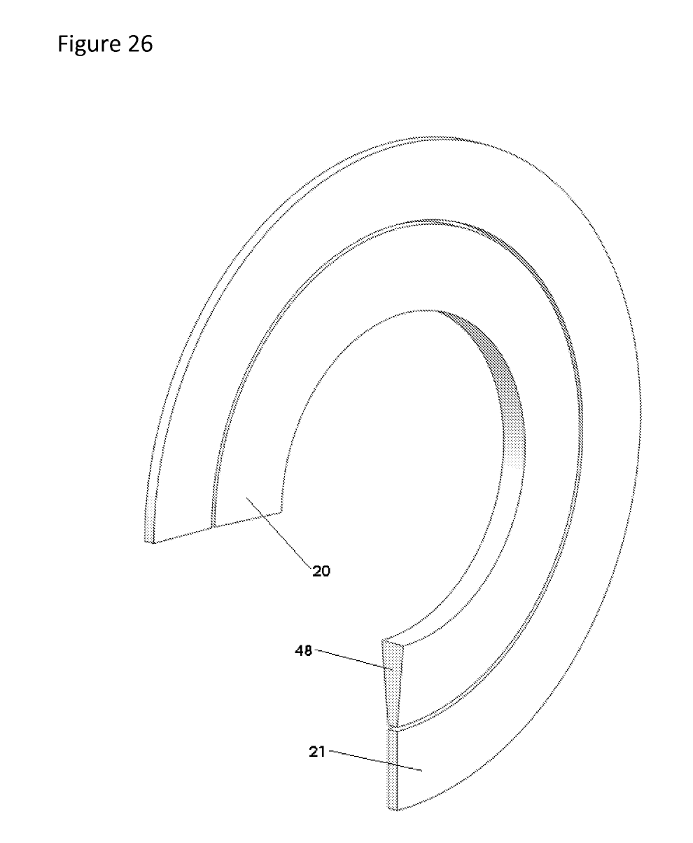

FIG. 26 depicts a rotating toroidal fluid mover 20, having a trapezoidal cross-section 48. The trapezoidal cross-sectional shape of fluid mover 48 corresponds to the shape of its resulting fluid flow field. Changing the cross-sectional shape of the fluid mover will change the shape of the fluid flow field. This trapezoidal shaped fluid flow field will direct fluid toward the heat sink element at a more acute angle. This more acute angle will result in fluid impinging on the heat sink element, increasing heat transfer efficiency. Although the toroidal fluid mover with a trapezoidal cross-section is shown, many shapes may result in fluid impinging on the heat sink element, including irregular shapes, shapes with protrusions, or bifurcated shapes.

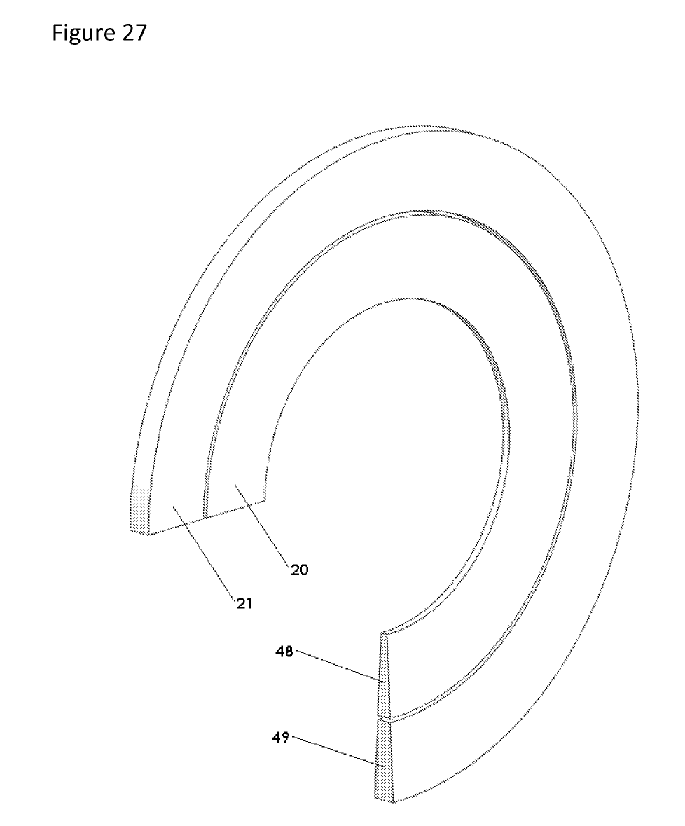

FIG. 27 depicts a rotating toroidal fluid mover 20 having a trapezoidal cross-section 48 and a heat sink element 21 having a trapezoidal cross-section 49. Although the fluid mover and heat sink element cross-sections have similar shapes with different dimensions, the primary surfaces on each side are coplanar, unlike FIG. 26. Although the toroidal fluid mover and heat sink element have coplanar surfaces, the fluid flow pattern will result in fluid impinging on the heat sink element, since the trapezoidal heat sink element will cause further widening of the fluid flow field. This further widening or the flow field, changes the fluid flow field direction, which results in more friction on the heat sink element surfaces. This additional friction improves heat transfer efficiency of the heat sink element.

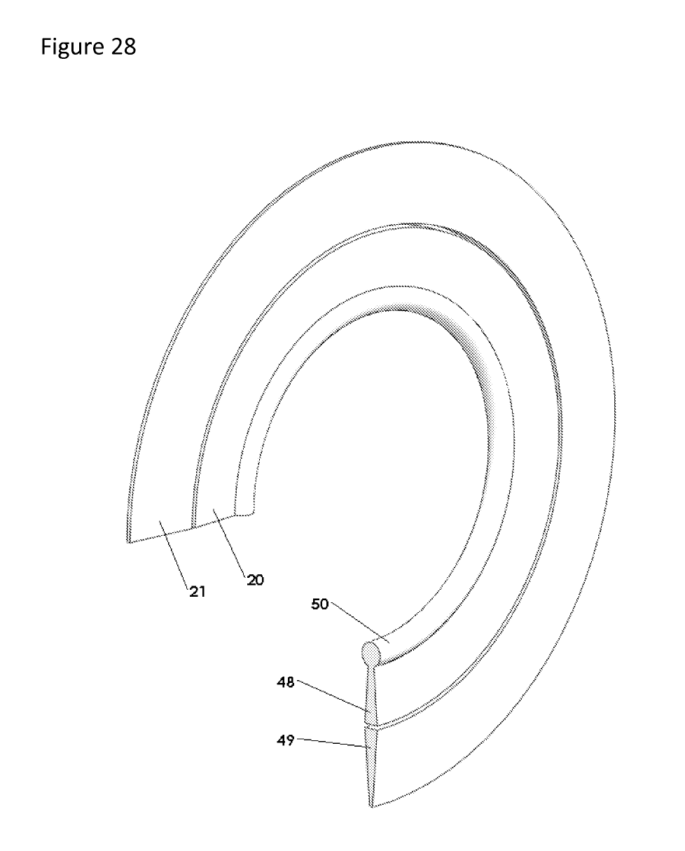

FIG. 28 depicts a rotating toroidal fluid mover 20 having a trapezoidal cross-section 48 with a leading edge feature 50. Heat sink element 21 also has a trapezoidal cross-section 49. The shape of leading edge feature 50 may be optimized to improve the mass fluid flow rate, by increasing surface area. Although, the trapezoidal shaped heat sink element is narrowing at the outer periphery, and may not cause widening of the flow field, it will cause the fluid flow field to converge, resulting in less aerodynamic drag, thereby reducing the fluid mover's rotational torque and horsepower.

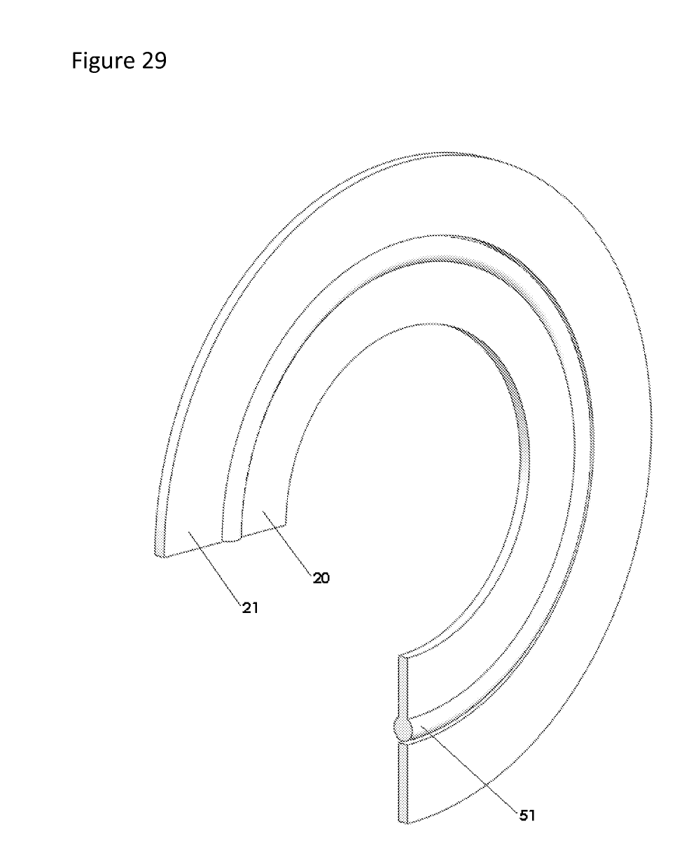

FIG. 29 depicts a rotating toroidal fluid mover 20 with a trailing edge feature 51. The shape of trailing edge feature 51 may be optimized to create turbulence on the heat sink element. This turbulent fluid flow field increases fluid impingement on the heat sink element, which increases the heat transfer efficiency of the heat sink element.

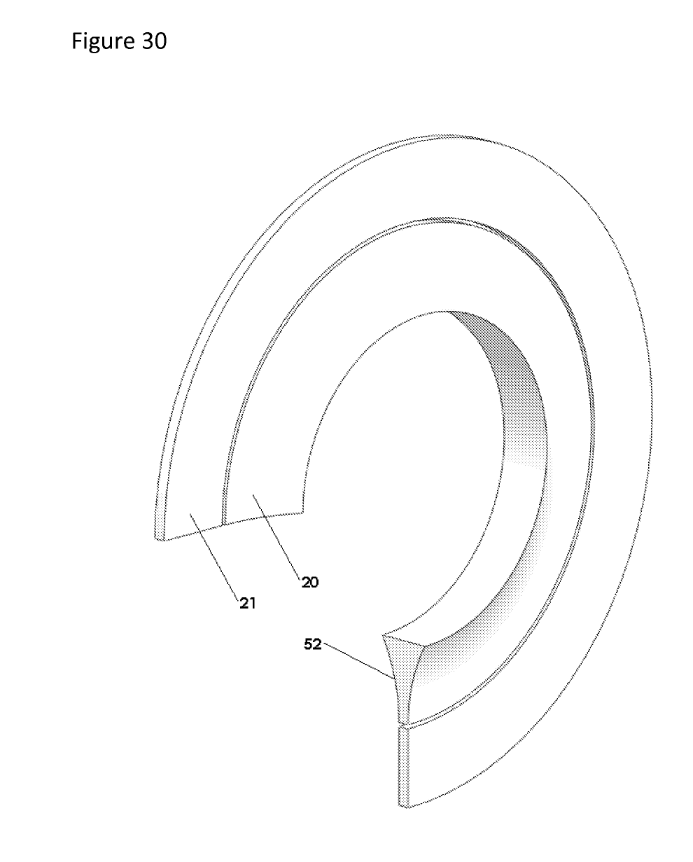

FIG. 30 depicts a rotating toroidal fluid mover 20 with curved surface feature 52. The curved surface feature 52 may be optimized to promote the fluid flow transition from axial to radial, thereby improving the fluid flow efficiency. Curved surface feature 52 is shown as symmetrical about the rotating fluid mover plane; however, these opposing surfaces need not be symmetrical. For example, the curved surface feature may be more pronounced on one side, if the axial fluid flow intake is at least partially restricted from the non-curved side.

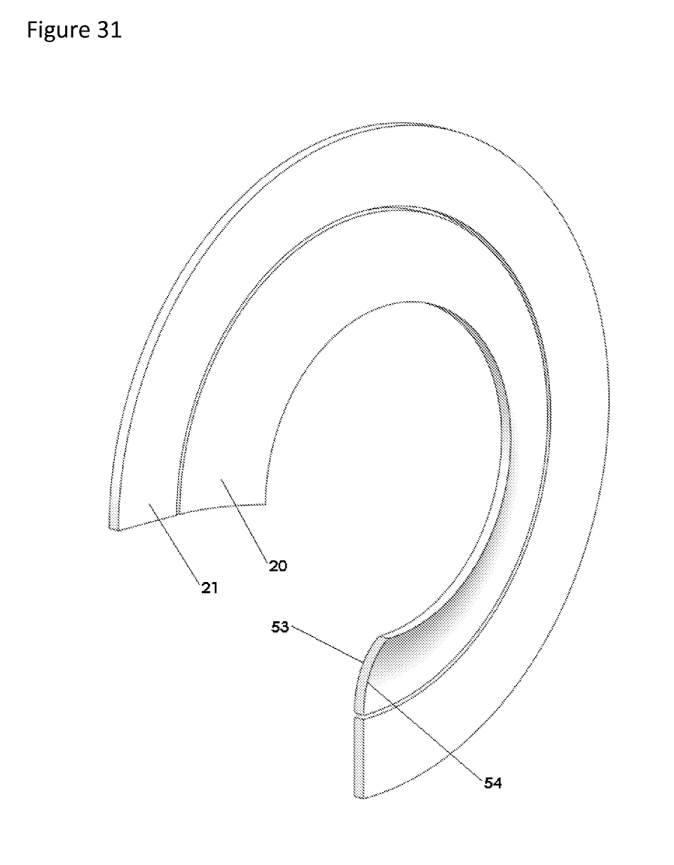

FIG. 31 depicts a rotating toroidal fluid mover 20 with coradially curved surfaces 53 and 54. The coradially curved surfaces may be optimized to promote the fluid flow transition from axial to radial, thereby improving fluid flow efficiency. Additionally, this curved toroidal fluid mover may have axially asymmetrical fluid flow rates. This axially asymmetrical fluid flow may be optimized to increase the total mass flow rate, where the axial fluid entrance on the convex side of the toroidal fluid mover may be at least partially obstructed.

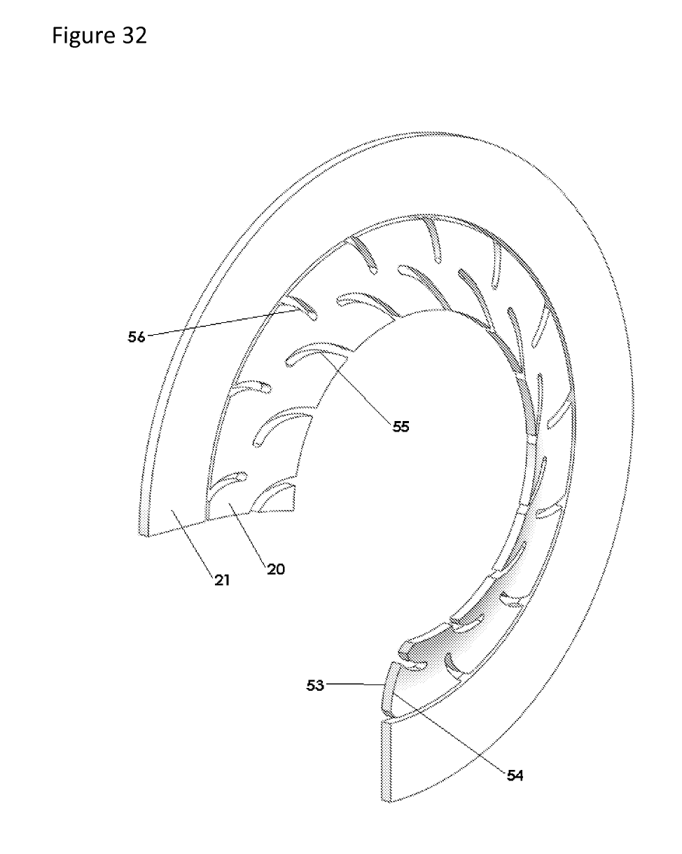

FIG. 32 depicts a rotating toroidal fluid mover 20 with coradially curved surfaces 53 and 54 having leading edge swept aperture 55 and trailing edge swept aperture 56. The shapes of these swept apertures may be optimized to improve the mass fluid flow rate and overall pressure. Although these swept apertures are shown as spiral shaped, they may have any shape, size, quantity, or pattern. Further, these swept features may be recessed from one or both sides, and may not be through features.

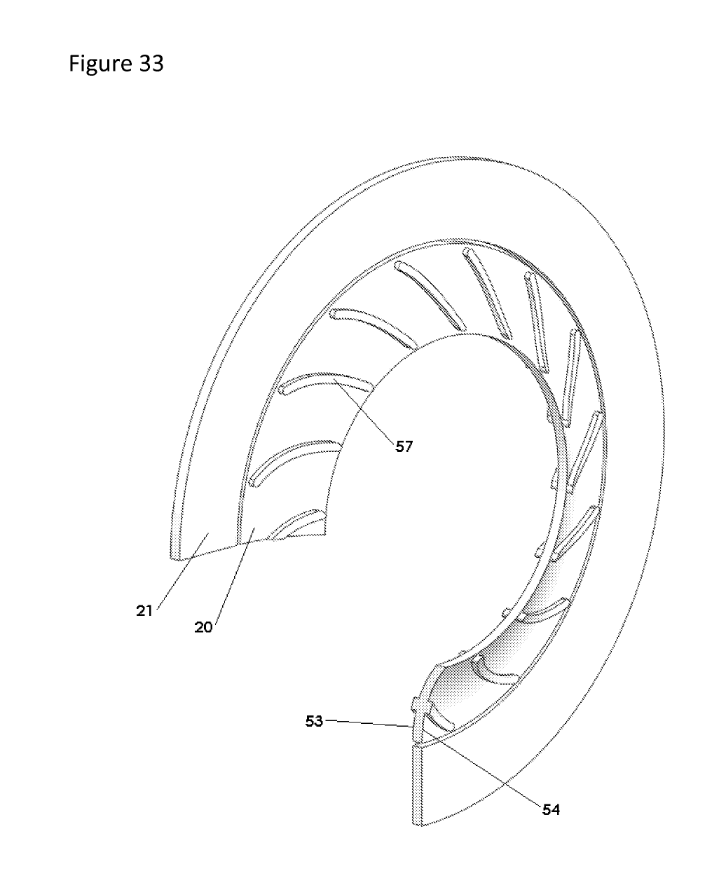

FIG. 33 depicts a rotating toroidal fluid mover 20 with coradially curved surfaces 53 and 54 having swept protruding surface features 57. These swept protruding surface features may be optimized to improve the mass fluid flow rate and overall pressure. Although these swept surface features are shown as spiral shaped, they may have any shape, size, quantity, or pattern. Furthermore, these swept protruding surface features may be on one side only, or may be more pronounced on either side. Although shown as symmetrical on both sides, these protruding swept surface features may be asymmetrical

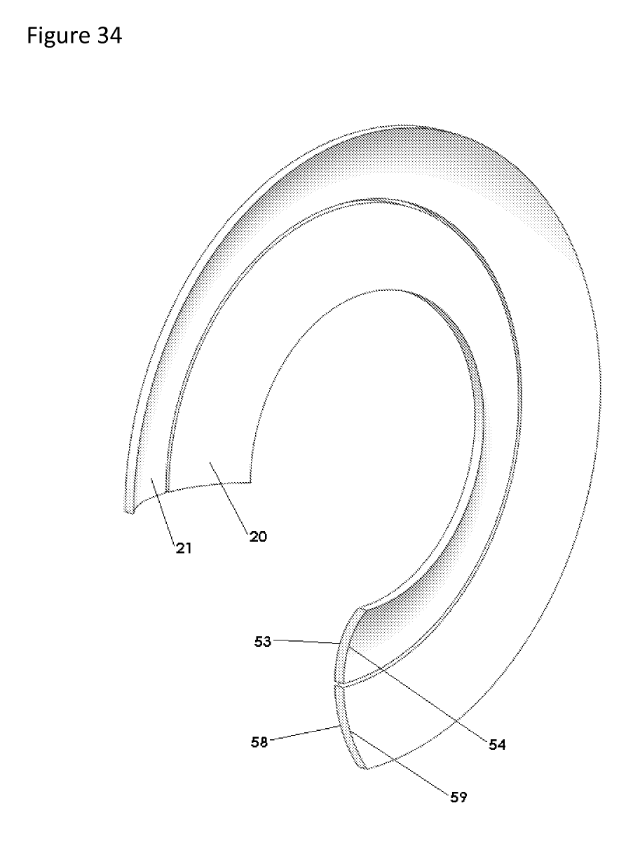

FIG. 34 depicts a rotating toroidal fluid mover 20 with coradially curved surfaces 53 and 54. Heat sink element 21 also has coradially curved surfaces 58 and 59. Combining coradially curved fluid mover and heat sink element surfaces may be optimized to further promote the fluid flow transition from axial to radial, thereby further improving the fluid flow efficiency. Additionally, this curved toroidal fluid mover may have axially asymmetrical fluid flow rates. This axially asymmetrical fluid flow may be optimized to increase the total mass flow rate, where the axial fluid entrance on the convex side may be at least partially obstructed.

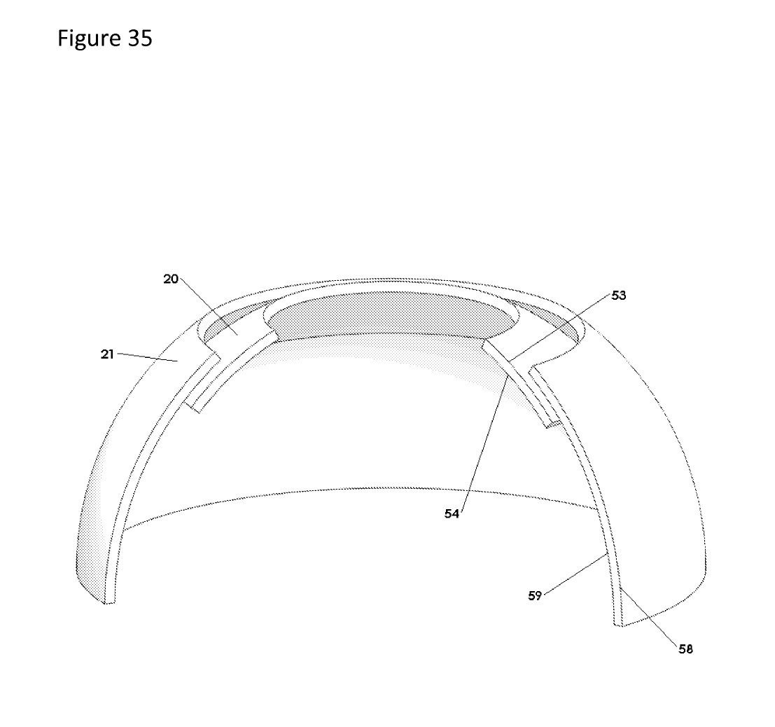

FIG. 35 depicts a rotating toroidal fluid mover 20, with coradially curved surfaces 53 and 54 and a heat sink element 21 having coradially curved surfaces 58 and 59. All four curved surfaces 53, 54, 58, and 59, may be coradial, resulting in a spherically shaped assembly. In addition, the toroidal fluid mover 20 is offset from the heat sink element 21. Further, the toroidal fluid mover 20 is at least partially overlapping the heat sink element 21. Since the fluid flow field is redirected by the curved surface of the heat sink element, the heat sink element enjoys the fluid flow impingement of such redirection, thereby improving the heat sink element heat transfer efficiency.

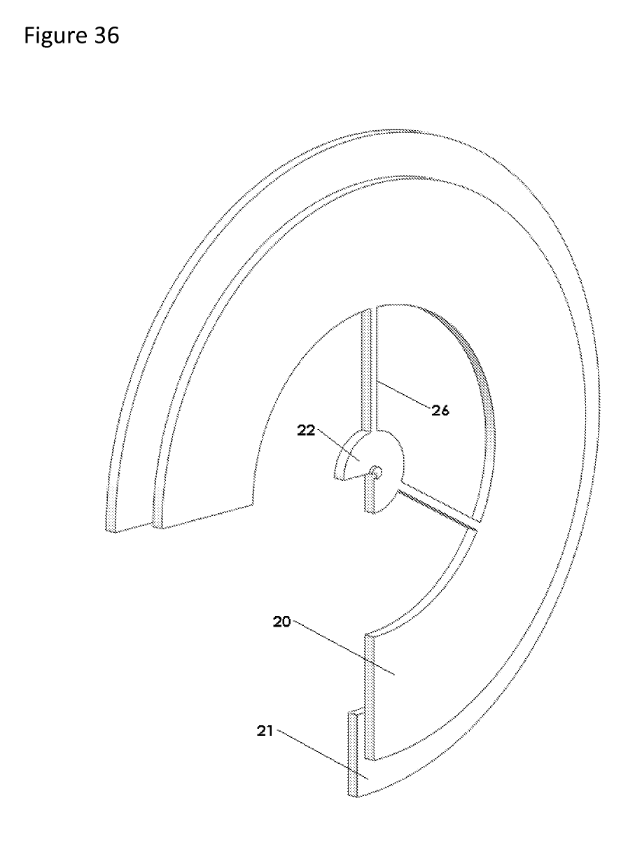

FIG. 36 depicts a rotating toroidal fluid mover 20 and a heat sink element 21. In addition, the toroidal fluid mover 20 is offset from the heat sink element 21. Further, the toroidal fluid mover 20 is at least partially overlapping the heat sink element 21. This overlapping region may be optimized to increase the heat transfer efficiency due to the close proximity of the overlapping surfaces. Although shown as partially overlapping, the toroidal fluid mover and heat sink element may be completely overlapping. Further, the toroidal fluid mover and heat sink element may be completely overlapping, where one or more radial boundaries exceed the other.

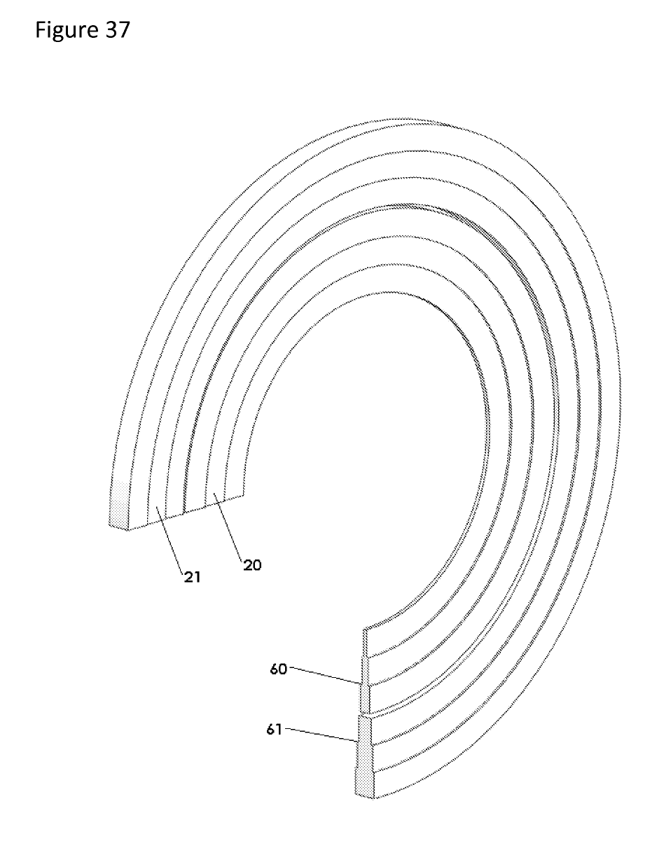

FIG. 37 depicts a rotating toroidal fluid mover 20 having a substantially trapezoidal cross-section with circumferential features 60. Heat sink element 21 has a substantially trapezoidal cross-section, with circumferential features 61. Circumferential feature 60 may be optimized to improve the mass fluid flow rate and overall pressure by disrupting the laminar flow and creating turbulence, thereby reducing the laminar thickness. Circumferential feature 61 may be optimized to improve heat transfer efficiency by also disrupting the laminar flow and creating turbulence, thereby increasing fluid impingement and reducing the laminar thickness. Circumferential features may be any revolved boss or cut, such as steps (as shown), protuberances, recessions, or apertures.

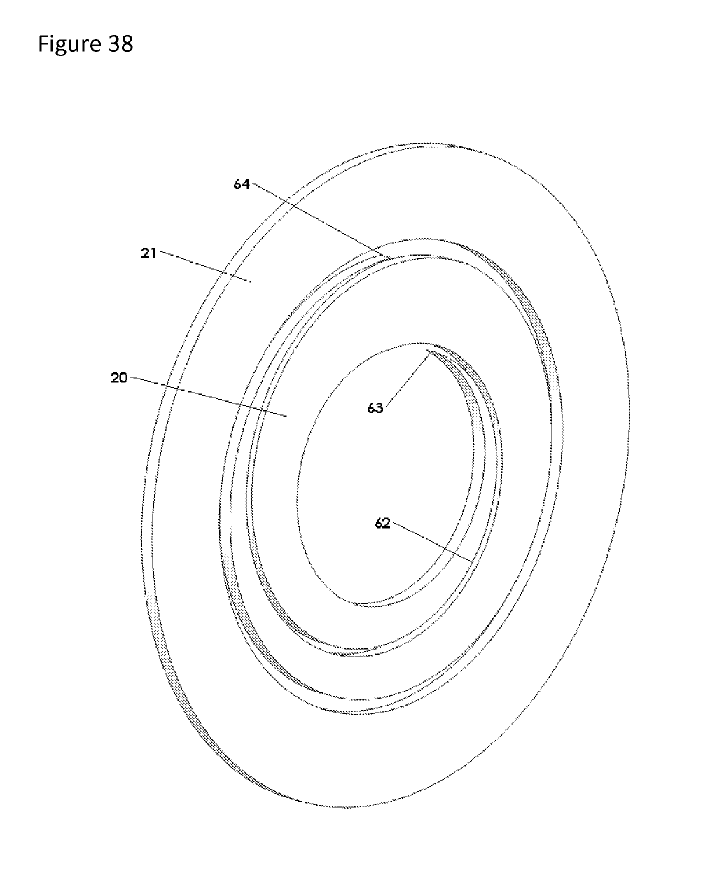

FIG. 38 depicts a rotating toroidal fluid mover 20 having a revolved spiral cut feature 62. Similar to circumferential feature 61, revolved spiral cut feature 62 may be optimized to improve the mass fluid flow rate and overall pressure, by disrupting the laminar flow from the toroidal fluid mover, and creating turbulence near the heat sink element, thereby reducing the laminar thickness on the heat sink element and thus improving heat transfer efficiency. The spiral shaped fluid mover has two ends 63 and 64. Depending on the angular direction, spiral ends 63 and 64 may be leading or trailing edges. For instance, from the viewer's perspective, if fluid mover 20 is rotating counter-clockwise, spiral end 63 will be the leading edge, and spiral end 64 will be the trailing edge. If fluid mover 20 is rotating clockwise, spiral end 64 will be the leading edge, and spiral end 63 will be the trailing edge. The leading edge of revolved spiral cut feature 62 may provide a fluid skiving affect, which increases local fluid velocity, and reduces local pressure, thereby improving flow from the higher pressure environment toward the lower pressure leading edge.

Therefore, from the viewer's perspective, if the spiral shaped fluid mover were rotating counter-clockwise, the fluid would flow axially from the higher pressure environment toward a smaller radius near leading edge 63, then turn and flow radially outward toward a larger radius near trailing edge 64, similar to FIG. 1 fluid flow pattern 19. Further, if the spiral shaped fluid mover were rotating clockwise, the fluid may flow radially inward from the higher pressure environment toward a larger radius near leading edge 64, then flow further radially inward toward a smaller radius near trailing edge 63, then turn and flow axially away from the spiral shaped fluid mover, which is the reverse direction of FIG. 1 fluid flow pattern 19. This reversed radial to axial fluid flow pattern allows greater overall design freedom.

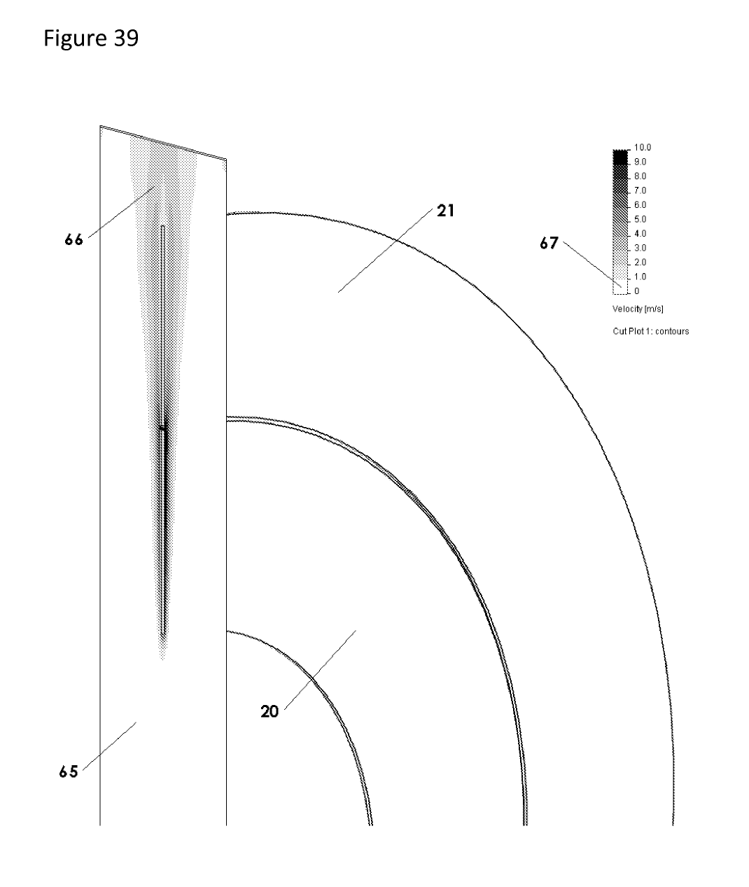

FIG. 39 depicts a section view of a rotating toroidal fluid mover 20, having an inside and outside radius of 35 mm and 60 mm respectively, rotating at 3,000 RPM, and a stationary heat sink element 21, having an inside and outside radius of 61 mm and 85 mm respectively, with a cut plot plane 65, showing the velocity contours 66 and a velocity scale 67. The fluid mover and heat sink shapes are similar to FIG. 1. The velocity contour 66 was derived using three dimensional (3D) computational fluid dynamics (CFD) analysis. This velocity contour clearly demonstrates the high velocity fluid flow field that is generated by the toroidal fluid mover. Further, it clearly depicts the high velocity fluid flow field engulfing the heat sink element. It even further depicts the high velocity fluid flow being fairly uniform on the primary planar surfaces of the heat sink element. Having heat sink element 21 surrounded by this high velocity fluid flow field and having high velocity fluid flow adjacent to the heat sink element primary planar surfaces, allows heat from the heat sink element to be efficiently transferred to this flow field. The average heat transfer coefficient on the surfaces of the heat sink element 21 is 59.9 W/m²/° K (watts per square meter per degree Kelvin), and the maximum heat transfer coefficient is 1,378 W/m²/° K. This translates to an average heat sink element surface temperature rise above ambient of 64.6° C. with a 100 watt heat load, or a thermal resistance of 0.646° C./W (degrees Centigrade per watt). Further, the volumetric efficiency of this embodiment is 0.136 W/° C./cc (watts per degree Centigrade per cubic centimeter); where current state of the art forced convection heat sinks have volumetric efficiencies around 0.003 W/° C./cc, which translates to a 4,400% (45 times greater) volumetric efficiency.

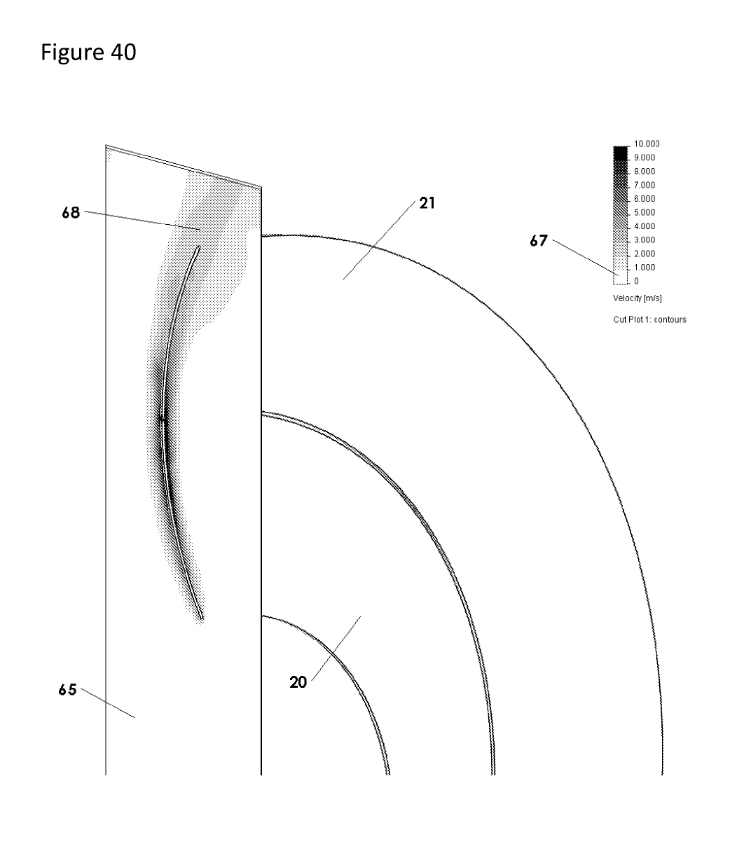

FIG. 40 depicts a section view of a rotating toroidal fluid mover 20 having a curved profile with an inside and outside radius of 35 mm and 60 mm, respectively, rotating at 3,000 RPM. A stationary heat sink element 21 has a curved profile with an inside and outside radius of 61 mm and 85 mm, respectively. A cut plot plane 65 shows the velocity contours 68 and a velocity scale 67. The fluid mover and heat sink shapes are similar to FIG. 34. The velocity contour 66 was derived using three dimensional (3D) computational fluid dynamics (CFD) analysis. This velocity contour clearly demonstrates the high velocity fluid flow field that is generated by the toroidal fluid mover. Further, it clearly depicts the high velocity fluid flow field engulfing the heat sink element. It also depicts the high velocity fluid flow being fairly uniform on the primary planar surfaces of the heat sink element. This velocity contour further depicts a more turbulent profile, than depicted in FIG. 39. Having heat sink element 21 surrounded by this high velocity fluid flow field and having high velocity fluid flow adjacent to the heat sink element primary planar surfaces allows heat from the heat sink element to be efficiently transferred to this flow field. The average heat transfer coefficient on the surfaces of the heat sink element 21 is 103.6 W/m²/K° (watts per square meter per degree Kelvin), and the maximum heat transfer coefficient is 1,870 W/m²/K°. This translates to an average heat sink element surface temperature rise above ambient of 38.1° C. with a 100 watt heat load, or a thermal resistance of 0.381 C/W. Further, the volumetric efficiency of this embodiment is 0.231 W/° C./cc (watts per degree Centigrade per cubic centimeter); where current state of the art forced convection heat sinks have volumetric efficiencies around 0.003 W/° C./cc, which translates to a 7,600% (77 times greater) volumetric efficiency. Notice the substantial heat transfer improvement over the embodiment described in FIG. 39. Given the size and rotational speed is the same as that in FIG. 39, the heat transfer improvement may be attributed to the fluid flow field shape. Since the primary surfaces of the heat transfer element are both curved, the fluid flow adjacent to these surfaces is more turbulent and less laminar. This turbulent flow is clearly seen in the velocity contour 68, especially when compared to the velocity contour 66.

The 70% performance improvement of FIG. 40 over FIG. 39 by virtue of curved surfaces, demonstrates the performance improvement potential of the various surface features described herein, such as fluid flow directional impingement, protuberances, recessions and apertures.

Thus, embodiments of the invention provide high velocity fluid movement. This is accomplished without measurable fluid flow pulsations. Thus, the invention provides for acoustic improvements over prior art fluid movers.

The foregoing description, for purposes of explanation, used specific nomenclature to provide a thorough understanding of the invention. However, it will be apparent to one skilled in the art that specific details are not required in order to practice the invention. Thus, the foregoing descriptions of specific embodiments of the invention are presented for purposes of illustration and description. They are not intended to be exhaustive or to limit the invention to the precise forms disclosed; obviously, many modifications and variations are possible in view of the above teachings. The embodiments were chosen and described in order to best explain the principles of the invention and its practical applications, they thereby enable others skilled in the art to best utilize the invention and various embodiments with various modifications as are suited to the particular use contemplated. It is intended that the following claims and their equivalents define the scope of the invention.

1. An apparatus, comprising:
a toroidal fluid mover;
a drive mechanism to rotate the toroidal fluid mover, such that the toroidal fluid mover directs axially received fluid at a smaller radius in a radial direction towards a greater radius to produce an axial-to-radial fluid flow field; and
a heat sink positioned within the axial-to-radial fluid flow field, wherein the heat sink is thermally coupled with a heat generating source and is at least partially filled with a fluid.

2. The apparatus of claim 1 wherein the toroidal fluid mover has a rectangular cross section.

3. The apparatus of claim 1 wherein the toroidal fluid mover and the heat sink are axially aligned.

4. The apparatus of claim 1 wherein the toroidal fluid mover and the heat sink are axially offset.

5. The apparatus of claim 1 wherein the toroidal fluid mover and the heat sink are not coaxial.

6. The apparatus of claim 1 wherein the heat sink includes recessed regions to receive the integrated circuits.

7. The apparatus of claim 1 wherein the heat sink includes a fluid pump.

8. The apparatus of claim 1 wherein the heat sink includes extended surfaces.

9. The apparatus of claim 1 wherein the heat sink includes a fluid flow diverting element.

10. The apparatus of claim 1 wherein the toroidal fluid mover includes extended surfaces.

11. The apparatus of claim 1 wherein the toroidal fluid mover includes recessed regions.

12. The apparatus of claim 1 wherein the toroidal fluid mover includes apertures.

13. The apparatus of claim 1 wherein the number of toroidal fluid movers and heat sinks are not equal.

14. The apparatus of claim 1 wherein the heat sink includes a first component connected to a second component by surface features.

15. The apparatus of claim 1 wherein the toroidal fluid mover has a trapezoidal cross section.

16. The apparatus of claim 1 wherein the heat sink has a trapezoidal cross section.

17. The apparatus of claim 1 wherein the toroidal fluid mover has a lead edge feature.

18. The apparatus of claim 1 wherein the toroidal fluid mover has a trailing edge feature.

19. The apparatus of claim 1 wherein the toroidal fluid mover has curved surfaces.

20. The apparatus of claim 1 wherein the toroidal fluid mover has coradially curved surfaces.

21. The apparatus of claim 1 wherein the heat sink has coradially curved surfaces.

22. The apparatus of claim 1 wherein the toroidal fluid mover has leading edge swept apertures.

23. The apparatus of claim 1 wherein the toroidal fluid mover has trailing edge swept apertures.

24. The apparatus of claim 1 wherein the toroidal fluid mover and the heat sink are spherically shaped.

25. The apparatus of claim 1 wherein the toroidal fluid mover has a revolved spiral cut.

26. The apparatus of claim 1 wherein the toroidal fluid mover has circumferential features.

27. The apparatus of claim 1 wherein the heat sink has circumferential features.

28. An apparatus, comprising:
a toroidal fluid mover with an outer perimeter;
a drive mechanism to rotate the toroidal fluid mover, such that the toroidal fluid mover directs axially received fluid at a smaller radius in a radial direction towards a greater radius to produce an axial-to-radial fluid flow field; and
a heat sink substantially surrounding the outer perimeter of the toroidal fluid mover and thereby being positioned within a radial region of the axial-to-radial fluid flow field, wherein the heat sink is thermally coupled with a heat generating source positioned within the radial region of the axial-to-radial fluid flow field.

29. The apparatus of claim 28 wherein the toroidal fluid mover has a rectangular cross section.

30. The apparatus of claim 28 wherein the toroidal fluid mover and the heat sink are axially aligned.

31. The apparatus of claim 28 wherein the toroidal fluid mover and the heat sink are axially offset.

32. The apparatus of claim 28 wherein the toroidal fluid mover and the heat sink are not coaxial.

33. The apparatus of claim 28 wherein the heat sink includes recessed regions to receive the integrated circuits.

34. The apparatus of claim 28 wherein the heat sink includes a fluid pump.

35. The apparatus of claim 28 wherein the heat sink includes extended surfaces.

36. The apparatus of claim 28 wherein the heat sink includes a fluid flow diverting element.

37. The apparatus of claim 28 wherein the toroidal fluid mover includes extended surfaces.

38. The apparatus of claim 28 wherein the toroidal fluid mover includes recessed regions.

39. The apparatus of claim 28 wherein the toroidal fluid mover includes apertures.

40. The apparatus of claim 28 wherein the number of toroidal fluid movers and heat sinks are not equal.

41. The apparatus of claim 28 wherein the heat sink includes a first component connected to a second component by surface features.

42. The apparatus of claim 28 wherein the toroidal fluid mover has a trapezoidal cross section.

43. The apparatus of claim 28 wherein the heat sink has a trapezoidal cross section.

44. The apparatus of claim 28 wherein the toroidal fluid mover has a lead edge feature.

45. The apparatus of claim 28 wherein the toroidal fluid mover has a trailing edge feature.

46. The apparatus of claim 28 wherein the toroidal fluid mover has curved surfaces.

47. The apparatus of claim 28 wherein the toroidal fluid mover has coradially curved surfaces.

48. The apparatus of claim 28 wherein the heat sink has coradially curved surfaces.

49. The apparatus of claim 28 wherein the toroidal fluid mover has leading edge swept apertures.

50. The apparatus of claim 28 wherein the toroidal fluid mover has trailing edge swept apertures.

51. The apparatus of claim 28 wherein the toroidal fluid mover and the heat sink are spherically shaped.

52. The apparatus of claim 28 wherein the toroidal fluid mover has a revolved spiral cut.

53. The apparatus of claim 28 wherein the toroidal fluid mover has circumferential features.

54. The apparatus of claim 28 wherein the heat sink has circumferential features.
